(19) United States
(12) Patent Application Publication
(10) Pub. No.: US 2026/0127338 A1
(43) Pub. Date: May 7, 2026

(54) 3D INVERSION METHOD OF DC METHOD USING SEISMIC DATA CONSTRAINTS

(71) Applicant: Central South University, Changsha (CN)

(72) Inventors: Zhenwei GUO, Changsha (CN); Yanyi WANG, Changsha (CN); Zhuo LIU, Changsha (CN); Yanjun CHEN, Changsha (CN); Jianxin LIU, Changsha (CN); Bochen WANG, Changsha (CN); Chengxi WANG, Changsha (CN)

(73) Assignee: Central South University, Changsha, HN (CN)

(21) Appl. No.: 19/441,015

(22) Filed: Jan. 6, 2026

(30) Foreign Application Priority Data
Mar. 19, 2025 (CN) 202510324895.2

(51) Int. Cl. G06F 30/23

(52) U.S. Cl. CPC G06F 30/23

(57) ABSTRACT

A 3D inversion method of DC method using seismic data constraints is disclosed, comprising processing of seismic data and inversion processing of resistivity data; by utilizing seismic wave interval velocity information to constrain the high-density electrical inversion, which can play a complementary role to a certain extent, it is beneficial to supplement the resolution of resistivity inversion with 3D seismic image information, reflect a boundary of subsurface electrical anomalous body, and further characterizes the boundary characteristics of anomalous body through comprehensive geological-geophysical analysis. Seismic data constraints are applied to 3D resistivity inversion, performing numerical simulation and inversion of electrical data under undulating terrain using the finite volume method and Gauss-Newton inversion method. Furthermore, the seismic anisotropic velocity tensor constraint is introduced for inversion to mitigate the non-uniqueness inherent in single-method inversion, yielding a more accurate 3D subsurface electrical structure and improving the resolution of longitudinal boundaries.

### TECHNICAL FIELD

The present disclosure relates to the field of geophysical exploration, in particular to a three-dimensional (3D) inversion method of a direct current (DC) method using seismic data constraints.

### BACKGROUND

Electrical exploration is a classic geophysical exploration method. While high-density electrical method results typically produce two-dimensional apparent resistivity profiles. Nevertheless, for complex geological conditions, two-dimensional inversion is difficult to meet the exploration requirements, and 3D inversion is required to accurately grasp the geometric position and physical characteristics of the target. There are two key challenges with the high-density electrical method: firstly, the resistivity inversion algorithm needs to be improved, and the calculation of 3D inversion requires improved algorithm and hardware conditions; secondly, the longitudinal resolution of subsurface resistivity distributions derived from high-density electrical data inversion is insufficient, making it difficult to delineate anomaly boundaries, which makes it challenging to accurately characterize the anomaly boundaries.

Joint inversion is one of the main methods to improve the quality of inversion at present. The joint inversion refers to the joint application of multiple geophysical observation data in geophysical inversion, and the same subsurface geological and geophysical model is jointly inverted through the relationship between rock physical properties and geometric parameters of geological bodies. Although joint inversion can use other geophysical exploration data to improve the interpretation accuracy of single electromagnetic data inversion, its corresponding calculation amount will also increase dramatically, which puts forward higher requirements for computer computing power and memory storage, thereby reducing the practical applicability of joint inversion.

Therefore, it is necessary to provide a 3D inversion method of the DC method using seismic data constraints to solve the above problems.

### SUMMARY

In order to solve the above problems, the present disclosure provides a 3D inversion method of a DC method using seismic data constraints. By utilizing seismic velocity information to constrain the high-density electrical inversion, which can play a complementary role to a certain extent, it is beneficial to supplement the longitudinal resolution of resistivity image information, invert a boundary of an subsurface electrical anomalous body, and further characterize the boundary characteristics of the anomalous body through comprehensive geological-geophysical information. The present disclosure studies 3D inversion of DC apparent resistivity constrained by seismic wave interval velocity, which applies seismic data constraints to 3D resistivity inversion, performs numerical simulation and inversion of electrical data under undulating terrain using the finite volume method and Gauss-Newton inversion method. Furthermore, the seismic anisotropic velocity tensor constraint is introduced for inversion to mitigate the non-uniqueness inherent in single-method inversion, yielding a more accurate 3D subsurface electrical structure and improving the resolution of longitudinal boundaries.

Therefore, the present disclosure adopts the 3D inversion method of the DC method using seismic data constraints, and has the following beneficial effects:
(1) In the present disclosure, the anisotropic characteristics of the formation interface are extracted through the seismic interval velocity structure tensor, the direction adaptive regularization constraint is constructed, thereby improving the vertical resolution of the resistivity inversion by more than 30% compared with the conventional method, and the anomalous body boundary positioning error≤5%.
(2) In the present disclosure, structural constraint terms driven by seismic data are introduced, which breaks the equivalence dilemma of electrical inversion, reduces the model space solution set by 40%-60%, while yielding notably effective false anomaly suppression.
(3) In the present disclosure, a finite volume method-Gauss-Newton mixed framework is employed, which enhances the stiffness matrix sparsity by 20% and reduces memory usage by 35%.
(4) In the present disclosure, the GPU accelerates structure tensor calculation and eigendecomposition, increasing the operational velocity of the key module by 8-12 times compared to CPU execution.
(5) In the present disclosure, the preconditioned conjugate gradient method (PCG) is combined with the adaptive regularization parameter strategy, which reduces the number of iterations by 50%-70%.
(6) In the present disclosure, the visualization and storage of both seismic data structure gradient calculations and weight calculations are implemented in a modular manner, thereby ensuring the readability and stability of the technical methodology.
(7) The present disclosure supports 3D model inversion at a million-unit level (grid scale ≥1,000×1,000×500) and satisfies complex geological modeling requirements; being compatible with undulating terrain and multi-scale exploration data input, it enables seamless integration with existing electrical method and seismic processing workflows.

Further detailed descriptions of the technical scheme of the present disclosure can be found in the accompanying drawings and embodiments.

### BRIEF DESCRIPTION OF THE DRAWINGS

FIG. 1 is an overall technical flowchart of a 3D inversion method of a DC method using seismic data constraints in an embodiment of the present disclosure;

FIG. 2 is a schematic diagram of 3D finite volume method forward modeling using a cell-centered approach in an embodiment of the present disclosure;

FIG. 3 is a cross-sectional view at y=0 of a 3D resistivity model in an embodiment of the present disclosure;

FIG. 4 is a 3D pseudo cross-sectional view of apparent resistivity of a 3D resistivity model in an embodiment of the present disclosure;

FIG. 5 is a 2D cross-sectional view at y=0 and x=+20 in an embodiment of the present disclosure;

FIG. 6 is a cross-sectional view at y=0 of a seismic velocity model of a 3D subsurface uniform half-space with a high-velocity anomalous body in an embodiment of the present disclosure.

FIG. 7 is a seismic velocity model diagram of a 3D subsurface uniform half-space with a high-velocity anomalous body in an embodiment of the present disclosure;

FIG. 8 is a cross-sectional comparison diagram at x=0 between a velocity model and a maximum principal eigenvalue λ₁ in an embodiment of the present disclosure;

FIG. 9 is a cross-sectional comparison diagram at y=0 between a velocity model and a maximum principal eigenvalue λ₁ in an embodiment of the present disclosure;

FIG. 10 is a cross-sectional comparison diagram at z=−20 m between a velocity model and a maximum principal eigenvalue λ₁ in an embodiment of the present disclosure;

FIG. 11 is a cross-sectional view at x=0 of similarity calculation and anisotropy weight calculation of a velocity model for a guide image in an embodiment of the present disclosure;

FIG. 12 is a cross-sectional view at y=0 of similarity calculation and anisotropy weight calculation of a velocity model for a guide image in an embodiment of the present disclosure;

FIG. 13 is a cross-sectional view at z=−10 m of similarity calculation and anisotropy weight calculation of a velocity model of a guide image in an embodiment of the present disclosure;

FIG. 14 is a cross-sectional view at z=−20 m of similarity calculation and anisotropy weight calculation of a velocity model of a guide image in an embodiment of the present disclosure;

FIG. 15 is a graph showing a variation in a root mean square error with a number of iterations of an inversion in an embodiment of the present disclosure;

FIG. 16 is a cross-sectional view at y=0 m of a 3D resistivity model in an embodiment of the present disclosure;

FIG. 17 is a cross-sectional view at y=0 m of Gauss-Newton inversion results and image-guided inversion results of 3D resistivity inversion in an embodiment of the present disclosure.

### DETAILED DESCRIPTION OF THE EMBODIMENTS

The technical scheme of the present disclosure is further explained below by drawings and embodiments.

Unless otherwise defined, the technical or scientific terms used in the present disclosure shall be those to which the present disclosure belongs.

The terms “including” or “comprising” and similar terminology used in the present disclosure mean that the elements preceding the term encompass the elements listed after the term, without excluding the possibility of also encompassing other elements. The terms “inside,” “outside,” “up,” “down,” and similar indications of direction or positional relationships are based on the orientation or positional relationships shown in the drawings. They are used solely for the purpose of facilitating the description of the present disclosure and simplifying the description, and are not intended to indicate or imply that the devices or elements referred to must have a specific orientation, be constructed in a specific orientation, or operate in a specific orientation. Therefore, it is not to be construed as a limitation on the present disclosure. When the absolute position of the described object changes, the relative positional relationship may also change accordingly. In the present disclosure, unless otherwise explicitly defined or limited, terms such as “attached” shall be interpreted broadly. For example, attachment may be a fixed connection, a detachable connection, or an integral structure; it may be a direct connection or an indirect connection via an intermediate medium; it may represent internal communication between two elements or an interactive relationship between two elements. Those skilled in the art will understand the specific meaning of the above terms in the context of the present disclosure based on the particular circumstances.

### Embodiment

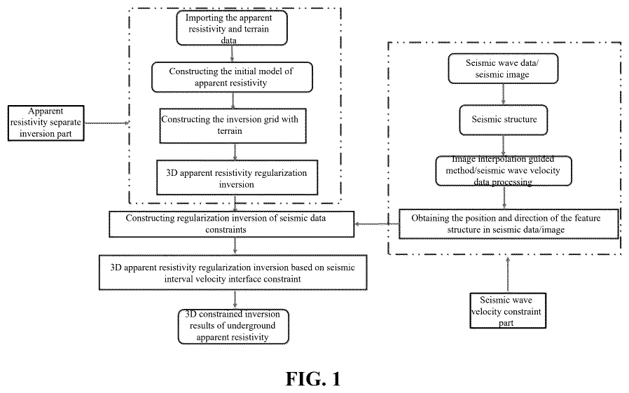

As shown in FIG. 1, a 3D inversion method of the DC method using seismic data constraints, including a processing of seismic data and an inversion of resistivity data;
wherein the processing of the seismic data includes the following steps:
Step 1: the 3D seismic velocity data or 3D seismic image related to the electric exploration data is processed, the air layer part is removed, the calculation of the structure tensor is performed to obtain structure tensor data, and the calculation of the structure tensor and eigendecomposition are accelerated through a hybrid calculation of GPU and CPU;
in step 1, the calculation method of the structure tensor data is as follows:
the gradient field is calculated by using the central difference combined with the Gaussian derivative kernel, and the 3D discrete gradient operator is defined as:

$$\{ \begin{matrix}{I}_{x} [ i , j , k ] = \frac{I [ i + 1 , j , k ] - I [ i - 1 , j , k ]}{2 Δ x} \\ {I}_{y} [ i , j , k ] = \frac{I [ i , j + 1 , k ] - I [ i , j - 1 , k ]}{2 Δ y} \\ {I}_{z} [ i , j , k ] = \frac{I [ i , j , k + 1 ] - I [ i , j , k - 1 ]}{2 Δ z}\end{matrix} ;$$

the high-frequency noise is eliminated by Gaussian smoothing:

$$= {G}_{σ} * {I}_{x} , = {G}_{z} * {I}_{z} , = {G}_{σ} * {I}_{z} ;$$

the discrete form of the Gaussian kernel G, is:

$${G}_{σ} [ n ] = \frac{1}{{( 2 π )}^{1 / 2} σ} {e}^{- \frac{{n}^{2}}{2 {σ}^{2}}} ;$$

the structure tensor is a second-order tensor matrix derived from the gradient, and the mathematical form of the 3D structure tensor is:

$${S}_{σ} = {G}_{σ} * [ \begin{matrix}{I}_{x}^{2} & {I}_{x} {I}_{y} & {I}_{x} {I}_{z} \\ {I}_{x} {I}_{y} & {I}_{y}^{2} & {I}_{y} {I}_{z} \\ {I}_{x} {I}_{z} & {I}_{y} {I}_{z} & {I}_{z}^{2}\end{matrix} ] = [ \begin{matrix}{S}_{xx} & {S}_{xy} & {S}_{xz} \\ {S}_{xy} & {S}_{yy} & {S}_{yz} \\ {S}_{xz} & {S}_{yz} & {S}_{zz}\end{matrix} ] ;$$

where Iₓ, I_{y} and I_{z} are gradients in each direction, S_{σ} is the structure tensor matrix corresponding to the node (i,j,k), *is the convolution operator, G_{σ} is the two-dimensional Gaussian difference operator, and σ controls the Gaussian function;
the expression of the Gaussian difference operator is:

$${G}_{σ} ( x , y , z ) = \frac{1}{{( 2 π σ )}^{3 / 2} {G}_{x} {G}_{y} {G}_{z}} {e}^{- ( \frac{{x}^{2}}{2 {σ}_{{x}^{2}}} + \frac{{y}^{2}}{2 {σ}_{{y}^{2}}} + \frac{{z}^{2}}{2 {σ}_{{z}^{2}}} )} ;$$

$${S}_{σ} = {λ}_{1} {v}_{1} {v}_{1}^{T} + {λ}_{2} {v}_{2} {v}_{2}^{T} + {λ}_{3} {v}_{3} {v}_{3}^{T} ( {λ}_{1} > {λ}_{2} > {λ}_{3} ) ;$$

the structure tensor matrix S_{σ} is the 3×3 real matrix, which is decomposed into three eigenvalues (λ₁,λ₂,λ₃) and three pairwise orthogonal eigenvectors (v₁,v₂,v₃), wherein the eigenvector v₁ corresponding to the largest eigenvalue denotes the direction pointing to the maximum local gradient energy, which is perpendicular to the structural boundary;
in the continuous medium, v₁ is perpendicular to the formation interface; in the sharp edge, v₁ is perpendicular to the fault surface; the second eigenvector v₂ is in the plane orthogonal to v₁, which denotes the secondary change direction of the local structure, the third eigenvector v₃ points to the direction with the minimum local change, which is typically parallel to the main extension direction of the structure, λ₁>>λ₃, denoteing strong anisotropy; λ₁≈λ₃, denoteing isotropy.

In step 1, based on the hardware environment of the NVIDIA Geforce RTX 4070 graphics card, the calculation of the structure tensor and eigendecomposition is accelerated through the hybrid calculation of GPU and CPU. The calculation process of 3D structure tensor analysis is achieved efficiently through the deeply customized CPU/GPU hybrid acceleration architecture.

GPU-CPU heterogeneous parallel computing: computationally intensive tasks such as structure tensor extraction and eigendecomposition are accelerated by the GPU, and the inversion core logic is scheduled by CPU multithreading. The multi-scale Gaussian filter replaces the conventional diffusion equation, which reduces the computational complexity of 3D similarity by 60%.

### GPU-CPU Heterogeneous Acceleration:

The structure tensor calculation and eigendecomposition in SimPEG native finite volume method forward are transplanted to GPU (based on CUDA acceleration), and the operation velocity of key modules is 10-15 times higher than that of SimPEG pure CPU; the core inversion logic (such as Jacobian matrix calculation, and data residual evaluation) is kept running in the CPU multithreaded environment to ensure the stability of the algorithm.

### Balancing Memory and Efficiency:

The SimPEG stiffness matrix is reconstructed by sparse matrix compression storage (CSR format), and the memory footprint is reduced by 40% (the memory requirement of the million-unit model is reduced from 64 GB to 38 GB); the preconditioned conjugate gradient method (PCG) is used to replace the default direct solver, and the number of iterations is reduced by 60% (decreasing from an average of 200 iterations to 80 iterations).

The calculation process is as follows:
1.1: the velocity model data is migrated from host memory to video memory of the graphics card through the asynchronous transmission channel of the CuPy library, and the zero-copy data interaction between CPU and GPU is achieved by using the unified memory architecture of CUDA8.0;
1.2: the parallelized 3D central difference method is utilized for gradient computation, with CUDA thread blocks handling differential operations on 32×32×32 voxel regions, and shared memory caching of local data is employed to reduce global memory access latency; and
1.3: during the construction process of the structure tensor, calculations of six independent components (Txx, Txy, Txz, Tyy, Tyz, Tzz) are mapped to different SM for the parallel execution, the element-wise operations corresponding to the components are vectorized through the broadcast mechanism of the GPU, and the separable convolution characteristics of the Gaussian filter are utilized to decompose the 3D convolution into a cascade of three 1D convolutions, which significantly reduces the computational complexity.

During the construction process of the structure tensor, the element-wise operations of the six components are performed matrix multiply-add fusion computation through the Tensor Core of the GPU, and the FP16 mixed precision mode is utilized to increase the calculation throughput to 83 TFLOPS. In the Gaussian filtering stage, the separable convolution characteristic is used to decompose the 3D filtering into three axial 1D convolutions. With the 72 MB on-chip storage of L2 cache, the filtering velocity can reach 120 million voxels per second. The eigendecomposition link calls the batch processing function to reconstruct the matrix operation of the entire 3D grid into a four-dimensional tensor. With the help of the 4070 24 MB L2 cache, a 98% cache hit rate is achieved, and the eigendecomposition time of the 512\hat{ }3 grid is controlled within 9.3 s, which is 17 times faster than the OpenBLAS multithreading of EPYC 7k62.

In the weight generation stage, parallelization of conditional logic is achieved through the CUDA kernel compiled by a Just-In-Time (JIT) compiler. An anisotropy enhancement factor of 2.0× is applied in the coherent region, a suppression coefficient of 0.5× is employed in the edge region, and masking operations are accelerated by the 192 texture mapping units of the 4070. Actual measurement data demonstrates that complete processing of the 512\hat{ }3 geological model requires only 28 s, with GPU computation accounting for 92% and CPU-assisted processing accounting for 8%. The whole system's power consumption remains stable at 320 W, achieving a computational energy efficiency ratio of 8.75 GFLOPS/W. This hybrid architecture fully leverages the advantages of parallel computing and the EPYC processor's multi-core data supply capabilities, providing a production-level solution for large-scale 3D geological modeling.
Step 2: the multi-scale Gaussian filtering method is adopted, the weight data is constructed through correlation determinations, the problems of fuzzy terrain boundary and invalid region interference of the geological model are solved by the mask processing method, thereby providing input data for anisotropic inversion; and the anisotropic coefficient α=1−e^{-kλ}^{ᵣ} is defined, and the structural strength is quantified by the eigenvalue ratio

$${λ}_{r} = \frac{{λ}_{1}}{{λ}_{3} + ϵ} .$$

The three-state weight function (edge suppression/structure enhancement/default smoothing) is constructed to achieve dynamic regularization intensity control based on seismic features.

In step 2, the similarity S is calculated by defining the Gaussian filters S₁ and S₂ of transverse structures and longitudinal structures, wherein the diffusion tensor D is determined by the feature vector and weight:

$$\frac{\partial m}{\partial t} = ∇ \cdot ( D ∇ m ) ;$$

the similarity S is defined as:

$$S = \frac{{S}_{2}}{{S}_{1} + ϵ} ;$$

the calculation of S₁ is divided into the following three steps, and the response of the horizontal continuous structure is enhanced by the transverse-priority filtering strategy:
(1) the transverse Gaussian filtering is performed along the x-y plane, and the anisotropic Gaussian kernel is shown as follows:

$$\begin{matrix}{I}_{temp 1} = {G}_{{σ}_{1}} * I \\ {σ}_{1} = ( 2 , 2 , 0 )\end{matrix} ;$$

here σₓ=σ_{y}=2, σ_{z}=0, which denotes only smoothing in the x-y plane;
(2) the longitudinal Gaussian filtering is performed along the z direction:

$$\begin{matrix}{I}_{temp 2} = {G}_{2} * {I}_{temp 1} \\ {σ}_{2} = ( 0 , 0 , 8 )\end{matrix} ;$$

here σₓ=σ_{y}=0, σ_{z}=8, which denotes filtering along the z direction;
(3) final smoothing:

$$\begin{matrix}{S}_{1} = {G}_{{σ}_{3}} * ( {I}_{temp 1} ⊙ {I}_{temp 2} ) \\ {σ}_{3} = 2\end{matrix} ;$$

where ⊙ denotes the multiplication of corresponding position elements of the matrix; wherein/is 3D image data, with the dimension of (x, y, z); σ₁ is the Gaussian kernel parameter of (σₓ=2, σ_{y}=2,), G_{σ}_{₁} is the 3D Gaussian filter with σ₁ as the parameter, only filtering in the x and y directions, and maintaining the original value in the z direction; and G_{σ}_{₃} is the 3D isotropic Gaussian filter for (σₓ=2, σ_{y}=2,), smoothing in all directions;
the calculation of S₂ is divided into the following three steps, and the response of the vertical continuous structure is enhanced by the longitudinal-priority filtering strategy:
\textcircled{1} the longitudinal Gaussian filtering is performed along the y=z plane:

$$\begin{matrix}{I}_{temp 3} = {G}_{{σ}_{4}} * I \\ {σ}_{4} = ( 0 , 8 , 8 )\end{matrix} ;$$

here σ_{y}=σ_{z}=8, σₓ=0, which denotes only smoothing in the y=z plane;
(2) the transverse Gaussian filtering is performed along the x direction:

$$\begin{matrix}{I}_{temp 4} = {G}_{5} * {I}_{temp 3} \\ {σ}_{5} = ( 2 , 0 , 0 )\end{matrix} ;$$

here σ_{y}=σ_{z}=0, σₓ=2, which denotes filtering along the x direction;
(3) final smoothing:

$$\begin{matrix}{S}_{2} = {G}_{{σ}_{6}} * ( {I}_{temp 3} ⊙ {I}_{temp 4} ) \\ {σ}_{6} = 8\end{matrix} ;$$

where ⊙ denotes the multiplication of corresponding position elements of the matrix.

During the mask processing in step 2, the essence of the mask is the binary matrix (0/1 matrix), which is used to mark the effective region of the data space and is highly consistent with the terrain processing. The mathematical form is expressed as:

$$M ( x ) = \{ \begin{matrix}1 , x ∈ valid region \\ 0 , x ∈ invalid region\end{matrix} ;$$

where M(x) denotes the spatial position-dependent binary matrix, configured to mark positions (x) in the data space which belong to the valid region (retain data) and which belong to the invalid region (suppress data). The data is selectively retained or suppressed by element multiplication:

$${D}_{m a s k e d} = D ⊙ M ;$$

where D is the original data matrix, M is denoted as the binary matrix generated by the function M(x), which is the same as the dimension of the original data matrix D, and D_{masked} denotes the result of the selective retention of the original data D through the mask matrix M; ⊙ denotes the multiplication of the corresponding position elements of the matrix, which ensures that the value of the invalid region is zero and avoids its influence on the subsequent calculation.

In order to suppress the gradient noise in the invalid region (air layer), the calculation of introducing the mask in the gradient calculation is:

$$∇ {I}_{m a s k e d} = ∇ I ⊙ M ;$$

the dynamic mask is introduced in the structural similarity calculation, and the boundary is kept clear through multiple applications of the mask, and the calculation is:
the initial data mask:

$${D}_{0} = D ⊙ M ;$$

the gaussian filter mask:

$${D}_{1} = {G}_{σ} ( {D}_{0} ) ;$$

the secondary mask:

$${D}_{2}^{m a s k e d} = {D}_{1} ⊙ M .$$

Through the multi-level and dynamic mask application strategy, the problems of fuzzy boundary and invalid region interference of the geological model are effectively addressed, which provides high-quality input data for subsequent anisotropic inversion.
Step 3: the anisotropy coefficient is calculated and defined with reference to the structural feature of the correlation by the eigenvalue ratio corresponding to the main feature direction and the normal feature direction, and the storage and the visualization of anisotropy weight are simultaneously output in a modular form.

In step 3, the process of anisotropy and weight calculation is as follows:
the anisotropy coefficient is calculated and defined by the eigenvalue ratio corresponding to the main feature direction and the normal feature direction:

$${λ}_{r} = \frac{{λ}_{1}}{{λ}_{3} + ϵ} ;$$

$$α = 1 - {e}^{- k {λ}_{r}} ;$$

where k is the positive real number, configured to adjust the influence of the eigenvalue ratio λᵣ on the anisotropy coefficient, k→0: wherein the anisotropy effect almost disappears, and the model degenerates into isotropic smoothing. The larger k results in more sensitive regional response, and the smaller k weakens anisotropic differences, and the value of k is [0.5,2.0].

Weight values of the following three constraints are obtained based on the determination of the calculated similarity.

When the similarity S is less than the value of the boundary determination condition, edge_threshold is determined as the edge region, and the smoothing intensity is reduced in the edge region, and the sharp boundary is retained.

When the similarity S is greater than the value of the coherence determination condition, coherence_threshold is determined as the structurally coherent region, and smoothing along the main direction is enhanced in the coherent region to suppress noise.

Other parts are set to 1:

$$ω = \{ \begin{matrix}a ( 1 + α ) & S > coherence\_threshold \\ b ( 1 - α ) & S < edge\_threshold \\ 1 & otherwise\end{matrix} ;$$

The inheritance of the implicit mask is also incorporated into the anisotropic weight generation: input data of weight calculation has been preprocessed by the mask, and the anisotropic weight after mask processing is expressed as:

$$W ( x ) = f ( ∇ {I}_{masked} , {λ}_{i} , {v}_{i} ) \cdot M ( x ) ;$$

where ƒ is the weight calculation method, λᵢ and vᵢ are the eigenvalue and the eigenvector of the structure tensor, respectively, and a and b are given weight coefficients.

The structure tensor is extracted based on the seismic interval velocity, and the anisotropic regularization weight matrix is constructed. Spatial consistency control between electrical boundaries and seismic interfaces is achieved by constraining the smoothing direction of the resistivity model with the direction of the principal eigenvector (v₁).

Based on the SimPEG inversion framework, a new seismic structure regularization module (Regularization.SeismicStructure) is added. Formation interface directional characteristics are extracted through the seismic velocity structure tensor, and the anisotropic smoothing constraint term is constructed. The resulting vertical resolution is 35% higher than the default SimPEG inversion (with measured fault boundary positioning error≤3%).

The multi-scale Gaussian filter-structure tensor fusion algorithm is proposed to replace the original isotropic diffusion filter of SimPEG to achieve efficient coupling of seismic features and electrical models, and false anomalies are reduced by 50%. The inversion processing of resistivity data includes the following steps:
S1: the calculation is performed by adopting the finite volume method, whereby the calculation region is discretized into non-overlapping control volumes or control voxels, conservation equations are applied to integrate the control volumes, a set of discrete equations is obtained by discretizing the integral equations, and the required apparent resistivity is acquired by solving the discrete equations;
The theoretical basis and fundamental equations for the point source field in 3D high-density resistivity method numerical simulation are established by the stable current field theory, it is assumed that there is a point source with current intensity I exists at point A on the ground (the default value in SimPEG is set to 1 A); where j is defined as the current density, E is defined as the electric field intensity, U is defined as the total potential, o is defined as the dielectric conductivity, and the relationships among these physical quantities are:

$$E = - ∇ U ; \qquad ( 1 )$$

$$j = σ E ; \qquad ( 2 )$$

Equation (2) is substituted into Equation (1):

$$j = - σ \cdot ∇ u ; \qquad ( 3 )$$

the divergence of Equation (3) is taken, obtaining:

$$∇ \cdot ( σ \cdot ∇ u ) = - ∇ \cdot j ; \qquad ( 4 )$$

according to the principle of charge conservation, the relationship between current density j and charge density q is:

$$∇ \cdot j = - \frac{\partial q}{\partial t} ; \qquad ( 5 )$$

thus the equation of potential u and charge density is:

$$∇ \cdot ( σ \cdot ∇ u ) = \frac{\partial q}{\partial t} ; \qquad ( 6 )$$

in the 3D numerical simulation, it is assumed that the position of the point charge e is (x₀, y₀, z₀), and the charge density q is obtained as follows:

$$q = e δ ( x - {x}_{0} ) δ ( y - {y}_{0} ) δ ( z - {z}_{0} ) ; \qquad ( 7 )$$

where δ is the Dirac function, and the current intensity is

$$I = - \frac{\partial e}{\partial t} ; \qquad ( 8 )$$

the fundamental equation of the 3D electric field potential of a point source is obtained:

$$∇ \cdot ( σ \cdot ∇ u ) = - I δ ( x - {x}_{0} ) δ ( y - {y}_{0} ) δ ( z - {z}_{0} ) ; \qquad ( 9 )$$

for the dipole point source, the current of the point source A (x_{A}, y_{A}, z_{A}) and the point source B (x_{B}, y_{B}, z_{B}) are I and −I, respectively. The fundamental equation of the 3D electric field potential is:

$$∇ \cdot ( σ \cdot ∇ u ) = - I ( δ ( x - {x}_{A} ) δ ( y - {y}_{A} ) δ ( z - {z}_{A} ) - δ ( x - {x}_{B} ) δ ( y - {y}_{B} ) δ ( z - {z}_{B} ) ) ; \qquad ( 10 )$$

for the boundary value, on the surface Gₛ, the normal component of the current density is zero:

$$\frac{\partial u}{\partial n} = 0 ∈ {Γ}_{S} \qquad ( 11 )$$

It is assumed that the anomalous body has no effect on the potential at the infinity boundary, the potential is obtained at the infinity boundary Gₛ:

$$u = \frac{c}{r} ∈ {Γ}_{∞} \qquad ( 12 )$$

R is a distance from the point source to the boundary. The derivation of Equation (12) is:

$$\frac{\partial u}{\partial n} + \frac{cos ( r , n ) u}{r} = 0 ∈ {Γ}_{∞} \qquad ( 13 )$$

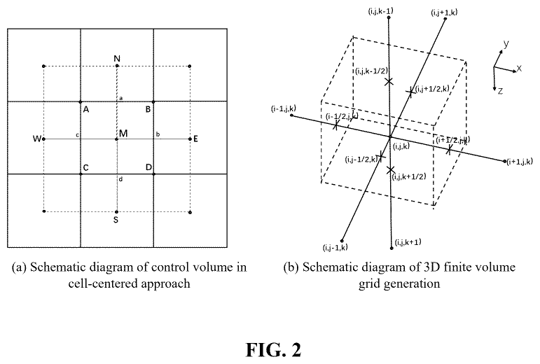

In step S1, in the grid generation and processing, the 3D region is discretized by the structural grid of the unit center method, as shown in FIG. 2. According to the theory of the finite volume method, the control volume of the unit where the node (i, j, k) is located is recorded as V_{i,j,k}, and the discrete source term of a control equation in the control volume is:

$$∇ \cdot ( σ ∇ u ) = - s ;$$

where u denotes the potential, o denotes the conductivity of the medium, and −s is defined as the source term denoting current injection or reception per unit volume;
the volume integral of the above equation is performed in the control volume:

$$\frac{1}{\vert {V}_{i , j , k} \vert} {\int }_{{V}_{i , j , k}} ∇ \cdot ( σ ∇ u ) dV = - \frac{1}{\vert {V}_{i , j , k} \vert} {\int }_{{V}_{i , j , k}} s dV ;$$

the Gauss theorem is applied to the left side expression to obtain:

$$\frac{1}{\vert {V}_{i , j , k} \vert} {\int }_{{V}_{i , j , k}} ∇ \cdot ( σ ∇ u ) dV = \frac{1}{\vert {V}_{i , j , k} \vert} {\int }_{\partial {V}_{i , j , k}} ( σ ∇ u ) \cdot n dS ;$$

in the control volume, V_{i,j,k} denotes the volume, ∂V_{i,j,k} is the surface area, surface integration and simplification are performed on the right side expression and simplified to obtain:

$${\int }_{\partial {V}_{i , j , k}} ( σ ∇ u ) \cdot n dS = {\int }_{{S}_{i + \frac{1}{2}}} σ ∇ u dS - {\int }_{{S}_{i - \frac{1}{2}}} σ ∇ u dS + {\int }_{{S}_{j + \frac{1}{2}}} σ ∇ u dS - {\int }_{{S}_{j - \frac{1}{2}}} σ ∇ u dS + {\int }_{{S}_{k + \frac{1}{2}}} σ ∇ u dS - {\int }_{{S}_{k - \frac{1}{2}}} σ ∇ u dS ;$$

since

$${S}_{i + \frac{1}{2}} = {S}_{i \frac{1}{2}} , {S}_{j + \frac{1}{2}} = {S}_{j - \frac{1}{2}} , and {S}_{k + \frac{1}{2}} = {S}_{k - \frac{1}{2}} ,$$

further simplifying to obtain:

$$\frac{1}{\vert {V}_{i , j , k} \vert} {\int }_{\partial {V}_{i , j , k}} ( σ ∇ u ) \cdot n dS = \frac{{( σ \frac{\partial u}{\partial x} )}_{i + \frac{1}{2} , j , k} - {( σ \frac{\partial u}{\partial x} )}_{i - \frac{1}{2} , j , k}}{{h}_{i}^{x}} + \frac{{( σ \frac{\partial u}{\partial y} )}_{i , j + \frac{1}{2} , k} - {( σ \frac{\partial u}{\partial y} )}_{i , j - \frac{1}{2} , k}}{{h}_{i}^{y}} + \frac{{( σ \frac{\partial u}{\partial z} )}_{i , j , k + \frac{1}{2}} - {( σ \frac{\partial u}{\partial z} )}_{i , j , k - \frac{1}{2}}}{{h}_{i}^{z}} ;$$

$${h}_{i}^{x} , {h}_{i}^{y} , and {h}_{i}^{z}$$

are the lengths of the control volume in the x, y, and z directions, respectively, wherein

$${( σ \frac{\partial u}{\partial x} )}_{i + \frac{1}{2} , j , k}$$

is expressed as:
directions, respectively, wherein

$${( σ \frac{\partial u}{\partial x} )}_{i + \frac{1}{2} , j , k} = {{σ}_{i + \frac{1}{2} , j , k} ( \frac{\partial u}{\partial x} )}_{i + \frac{1}{2} , j , k} ;$$

is the harmonic mean of the two control volumes of the conductivity in the x direction:

$${σ}_{i + \frac{1}{2} , j , k} = {{h}_{i + \frac{1}{2}}^{x} ( {\int }_{{x}_{i}}^{{x}_{i + 1}} {σ}^{- 1} ( x , y , z ) dx )}^{- 1} ;$$

in the above equation:

$${h}_{i + \frac{1}{2}}^{x} = {x}_{i + 1} - {x}_{i} = ( {h}_{i + 1}^{x} + {h}_{i}^{x} ) / 2 ;$$

thus:

$${( σ \frac{\partial u}{\partial x} )}_{i + \frac{1}{2} , j , k} = {h}_{i + \frac{1}{2}}^{x} {( \frac{{h}_{i}^{x}}{2 {σ}_{i , j , k}} + \frac{{h}_{i + 1}^{x}}{2 {σ}_{i + 1 , j , k}} )}^{- 1} ( \frac{{u}_{i + 1 , j , k} - {u}_{i , j , k}}{{h}_{i + \frac{1}{2}}^{x}} ) ;$$

$${( σ \frac{\partial u}{\partial x} )}_{i - \frac{1}{2} , j , k} = {h}_{i + \frac{1}{2}}^{x} {( \frac{{h}_{i}^{x}}{2 {σ}_{i , j , k}} + \frac{{h}_{i - 1}^{x}}{2 {σ}_{i - 1 , j , k}} )}^{- 1} ( \frac{{u}_{i , j , k} - {u}_{i - 1 , j , k}}{{h}_{i - \frac{1}{2}}^{x}} ) ;$$

$$\frac{1}{\vert {V}_{i , j , k} \vert} {\int }_{\partial {V}_{i , j , k}} ( σ ∇ u ) \cdot n dS = \frac{{σ}_{i + \frac{1}{2} , j , k} ( \frac{{u}_{i + 1 , j , k} - {u}_{i , j , k}}{{h}_{i + \frac{1}{2}}^{x}} ) - {σ}_{i - \frac{1}{2} , j , k} ( \frac{{u}_{i , j , k} - {u}_{i - 1 , j , k}}{{h}_{i - \frac{1}{2}}^{x}} )}{{h}_{i}^{x}} + \frac{{σ}_{i , j + \frac{1}{2} , k} ( \frac{{u}_{i , j + 1 , k} - {u}_{i , j , k}}{{h}_{j + \frac{1}{2}}^{y}} ) - {σ}_{i , j - \frac{1}{2} , k} ( \frac{{u}_{i , j , k} - {u}_{i , j - 1 , k}}{{h}_{j - \frac{1}{2}}^{y}} )}{{h}_{i}^{y}} + \frac{{σ}_{i , j , k + \frac{1}{2}} ( \frac{{u}_{i , j , k + 1} - {u}_{i , j , k}}{{h}_{k + \frac{1}{2}}^{z}} ) - {σ}_{i , j , k - \frac{1}{2}} ( \frac{{u}_{i , j , k} - {u}_{i , j , k - 1}}{{h}_{k - \frac{1}{2}}^{z}} )}{{h}_{i}^{z}} = - \frac{1}{\vert {V}_{i , j , k} \vert} {\int }_{{V}_{i , j , k}} s dV ;$$

wherein the source term is:

$$\frac{1}{\vert {V}_{i , j , k} \vert} {\int }_{{V}_{i , j , k}} s dV = \{ \begin{matrix}I & ( {x}_{a} , {y}_{a} , {z}_{a} ) ∈ {V}_{i , j , k} \\ 0 & ( {x}_{a} , {y}_{a} , {z}_{a} ) ∉ {V}_{i , j , k}\end{matrix} .$$

S2: resistivity inversion under seismic data constraint is obtained by updating the framework of Gauss-Newton inversion, the linear system is solved by the preconditioned conjugate gradient (PCG) method, the inversion is performed with an adaptive regularization parameter guided by the L-curve criterion, and the inversion effect is evaluated by using the root mean square error;
The hybrid solution framework combining the FVM and Gauss-Newton method enables rapid generation and sparse storage of the forward stiffness matrix. Optimization is performed using the Jacobi-preconditioned conjugate gradient (PCG) method, combined with a dynamic adjustment strategy for adaptive regularization parameters guided by the L-curve criterion.

The L-curve criterion-driven regularization parameter adaptation mechanism is extended in the Inversion.BaseInvProblem class of SimPEG, achieving dynamic adjustment of smoothing intensity and data fitting weight, eliminating manual trial-and-error parameter adjustment, and achieving 25% improvement in inversion result stability.

A β-cooling strategy (β=β₀/γⁿ) is designed, strong regularization is applied for noise suppression at the initial stages, and weak regularization is applied for detail restoration at later stages, and the root mean square error (RMS) is reduced by 18% relative to the SimPEG fixed-value strategy.

In step S2, in the model discretization and grid generation, the control equation is the current continuity equation:

$$∇ \cdot ( σ ∇ ϕ ) = - I δ ( r - {r}_{s} ) ;$$

the FVM is used for spatial discretization to generate a stiffness matrix A, and the linear system is obtained:

$$A ( σ ) ϕ = q ;$$

in geophysical inversion, the simplest objective function is:

$$φ ( m ) = {‖ {W}_{d} ( F ( m ) - d ) ‖}^{2} ;$$

$$where$$

$$m = {[ {m}_{1} , {m}_{2} , … , {m}_{M} ]}^{T} ;$$

$$d = {[ {d}_{1} , {d}_{2} , … , {d}_{N} ]}^{T} ;$$

$${W}_{d} = [ \begin{matrix}\frac{1}{{σ}_{1}} & & & \\ & \frac{1}{{σ}_{2}} & & \\ & & ⋱ & \\ & & & \frac{1}{{σ}_{N}}\end{matrix} ] ;$$

m is a model vector, d is a data vector, F(m) is a forward response of the model vector m, W_{d} is a data-weighting matrix for the measured data, and σᵢ is a standard deviation of the i^{th} number.

The inversion objective function after adding Tikhonov regularization constraint is:

$$φ ( m ) = {‖ {W}_{d} ( F ( m ) - d ) ‖}^{2} + λ {‖ {W}_{m} ( m - {m}_{apr} ) ‖}^{2} ;$$

with reference to Gauss-Newton inversion, the total objective function utilized in the present disclosure is:

$$φ ( m ) = {φ}_{d} ( m ) + {φ}_{m} ( m ) = \frac{1}{2} {‖ {W}_{d} ( F ( m ) - d ) ‖}^{2} + \frac{β}{2} {‖ {W}_{m} ( m - {m}_{a p r} ) ‖}^{2} ;$$

the data fitting term φ_{d}(m) is calculated by calculating the L2 norm of the weighted residual, and the regularization term φₘ(m) is set to a combination of the minimum model constraint term and the weighted directional smoothing constraint term:

$${φ}_{m} ( m ) = {α}_{s} {‖ m ‖}^{2} + {α}_{x} {‖ {\partial }_{x} m ‖}^{2} + {α}_{y} {‖ {\partial }_{y} m ‖}^{2} + {α}_{z} {‖ {\partial }_{z} m ‖}^{2} ;$$

the sensitivity matrix J[m] is calculated as: the element Jᵢⱼ reflects the sensitivity of the model parameters to the data, and the application of weights can balance the update of different parameters. The sensitivity matrix is expressed as:

$$J [ m ] = \frac{d F ( m )}{d m} = P ( \frac{d u}{d m} ) ;$$

The over-updates of deep units are suppressed by dynamically adjusting the sensitivity weight, and the sensitivity weight is set as follows:

$${W}_{j j} = \frac{1}{\sqrt{{\sum }_{i} {J}_{i j}^{2}}} ;$$

the Jacobi preconditioner is used to improve the condition number of the matrix, and the condition number of the matrix is defined as:

$$κ ( A ) = ‖ A ‖ \cdot ‖ {A}^{- 1} ‖ ;$$

where ∥⋅⋅ denotes the matrix norm (typically being the spectral norm):
a larger condition number indicates that the matrix is closer to singularity (non-invertibility), making the numerical solution more sensitive to errors, and leading to slower convergence of iterative methods;
a smaller condition number indicates that the matrix is closer to being “well-conditioned”, leading to faster convergence of iterative methods and more stable solutions.

In the inversion problem, each step of the Gauss-Newton method needs to solve the linear system:

$$H δ m = - ∇ Φ ;$$

where the Hessian matrix is approximately equal to:

$$H = {J}^{T} {W}_{d}^{T} {W}_{d} J + β {W}_{m}^{T} {W}_{m}$$

where the coefficient matrix (Hessian matrix) is typically ill-conditioned (high condition number), leading to the slow convergence of the conjugate gradient method (CG).

The objective of a preconditioner is to transform the original linear system into an equivalent but more tractable form by constructing the preconditioned matrix M:

$${M}^{- 1} A x = {M}^{- 1} b ;$$

ideally, the condition number of the new matrix M⁻¹A satisfies κ(M⁻¹A)<<κ(A), thus accelerating the convergence of iterative methods.

Jacobi preconditioner is the simplest preconditioner, which is constructed as follows:

$$M = {diag ( A )}^{- 1} ;$$

specifically, the reciprocal of the diagonal elements of matrix A is taken to form the diagonal matrix.

The constructed Jacobi preconditioner first calculates the diagonal element hᵢᵢ of the Hessian matrix, and then constructs the diagonal matrix M as the preconditioner, whose elements are the reciprocals of the diagonal elements:

$${h}_{i i} = {\sum }_{j} {( {W}_{d} J )}_{j i}^{2} + β {\sum }_{j} {( {W}_{m} )}_{j i}^{2} ;$$

where the first term is the weighted column square sum of the sensitivity matrix J, and the second term is the column square sum of the regularization matrix Wₘ multiplied by β;
the constructed preconditioner M is:

$${M}_{i i} = \frac{1}{{h}_{i i}} ;$$

the above Hessian matrix can be further expressed as:

$$H = [ \begin{matrix}{h}_{11} & {h}_{12} & … & {h}_{1 n} \\ {h}_{21} & {h}_{22} & … & {h}_{2 n} \\ ⋮ & ⋮ & ⋱ & ⋮ \\ {h}_{n 1} & {h}_{n 2} & … & {h}_{nn}\end{matrix} ] ;$$

the preconditioner M can be expressed as:

$$M = [ \begin{matrix}\frac{1}{{h}_{11}} & \frac{1}{{h}_{12}} & … & \frac{1}{{h}_{1 n}} \\ \frac{1}{{h}_{21}} & \frac{1}{{h}_{22}} & … & \frac{1}{{h}_{2 n}} \\ ⋮ & ⋮ & ⋱ & ⋮ \\ \frac{1}{{h}_{n 1}} & \frac{1}{{h}_{n 2}} & … & \frac{1}{{h}_{nn}}\end{matrix} ] ;$$

the gradient calculation is as follows:

$$g ( m ) = {J [ m ]}^{T} {W}_{d}^{T} {W}_{d} ( F ( m ) - {d}_{o b s} ) + β {W}_{m}^{T} {W}_{m} ( m - {m}_{r e f} ) ;$$

a core of the Gauss-Newton inversion method is to perform the first-order Taylor expansion to the nonlinear forward response F(m), wherein the current model is

$${m}_{k} , F ( {m}_{k + 1} ) = F ( {m}_{k} ) + {J}_{k} ( {m}_{k + 1} - {m}_{k} ) ;$$

where Jₖ is the Jacobian matrix, the element is denoted by:

$${J}_{i j} = \frac{\partial {F}_{i}}{{dm}_{j}^{′}} ;$$

where Fᵢ is denoted as the i^{th} forward response, m; denotes the j^{th} model parameter, and Jᵢⱼ is the partial derivative of the i^{th} observation data to the j^{th} model parameter;
the updated approximate objective function is:

$$Φ ( {m}_{k + 1} ) = \frac{1}{2} {‖ {W}_{d} ( d - F ( {m}_{k} ) - {W}_{d} {J}_{k} ( {m}_{k + 1} - {m}_{k} ) ) ‖}^{2} + \frac{β}{2} {‖ {W}_{m} ( {m}_{k + 1} - {m}_{ref} ) ‖}^{2} ;$$

where W_{d} is the data-weighting matrix for the measured data;
the derivative of Φ(mₖ₊₁) with respect to mₖ₊₁ is computed and set the derivative to zero, to obtain the linear system:

$$( {J}_{k}^{T} {W}_{d}^{T} {W}_{d} {J}_{k} + {βW}_{m}^{T} {W}_{m} ) ( {m}_{k + 1} - {m}_{k} ) = {J}_{k}^{T} {W}_{d}^{T} {W}_{d} ( d - F ( {m}_{k} ) ) - {βW}_{m}^{T} {W}_{m} ( {m}_{k} - {m}_{k + 1} ) ;$$

the model update equation is:

$${m}_{k + 1} = {m}_{k} + αδ m ; wherein$$

$$δ m = {( {J}_{k}^{T} {W}_{d}^{T} {W}_{d} {J}_{k} + β {W}_{m}^{T} {W}_{m} )}^{- 1} ;$$

the resulting linear system is solved by the preconditioned conjugate gradient method (PCG), which is the conjugate gradient (CG) method combined with the precondition:
parameters are initialized by setting the initial model update to zero, and the initial residual is equal to the gradient vector:

$$\begin{matrix}δ {m}_{0} = 0 \\ {r}_{0} = ℊ - H δ {m}_{0}\end{matrix} ;$$

where g denotes the gradient vector, and H denotes the Hessian matrix;
the convergence is accelerated by applying the preconditioned matrix M to the residual, the initial search direction is set as the preconditioned residual:

$$\begin{matrix}{z}_{0} = {M}^{- 1} {r}_{0} \\ {p}_{0} = {z}_{0}\end{matrix} ;$$

where z₀ denotes the preconditioned residual, r₀ denotes the initial residual, and p₀ denotes the initial search direction,
the iteratively updated step size αₖ is calculated by minimizing the quadratic function ƒ(δm):

$$f ( δ m ) = \frac{1}{2} ( δ {m}^{T} H δ m - {ℊ}^{T} δ m ) ;$$

$$\frac{\partial f}{\partial α} = 0$$

is satisfied at the minimum point along direction pₖ, obtaining:

$${α}_{k} = \frac{{r}_{k}^{T} {z}_{k}}{{p}_{k}^{T} {Hp}_{k}} ;$$

wherein the molecule is the inner product of the preconditioned residual, configured to measure current residual energy; rₖ denotes the residual of the k^{th} iteration; zₖ denotes the preconditioned residual, to adjust the distribution of the residual through the preconditioned matrix M, improve the condition number of the linear system, and accelerate the convergence; the denominator is the energy of the search direction under the Hessian metric, pₖ denotes the search direction of the k^{th} iteration;
wherein subsequent model updates and residual updates are:

$$δ {m}_{k + 1} = δ {m}_{k} + {α}_{k} {p}_{k} ;$$

$${r}_{k + 1} = {r}_{k} - {α}_{k} {p}_{k} ;$$

the model correction is updated by stepping αₖ along the search direction; preconditions are applied and new directions are calculated, the new residual is processed by the precondition, and the ill-conditionality of the Hessian matrix is eliminated:

$${z}_{k + 1} = {M}^{- I} {r}_{k + 1} ;$$

βₖ is updated to measure the old and new residual energy ratio, and the search direction is adjusted to obtain:

$${β}_{k} = \frac{{r}_{k + 1}^{T} {z}_{k + 1}}{{r}_{k}^{T} {z}_{k}} ;$$

the conjugate direction is generated by combining the current preconditioned residual with the previous direction:

$${p}_{k + 1} = {z}_{k + 1} + {β}_{k} {p}_{k} ;$$

where βₖ denotes the adjustment coefficient of the conjugate direction;
the termination condition is set to terminate the iteration when the residual norm is reduced to 1% of the initial residual to balance the computational efficiency and the accuracy, thus avoiding the excessive iteration:

$$\frac{‖ {r}_{k} ‖}{‖ ℊ ‖} < tolCG ;$$

where ∥g∥ denotes the norm of the initial residual r₀=g, configured as the convergence benchmark.

In S2, in the process of the adaptive regularization, the L-curve criterion is used to determine the optimal value of regularization parameter, and the objective function of the regularization problem can be defined as:

$${min}_{x} \{ {‖ Ax - b ‖}_{2}^{2} + {λ}^{2} {‖ Lx ‖}_{2}^{2} \} ;$$

wherein A is the coefficient matrix, b is the observation data; L is the regularization matrix, and λ is the regularization parameter;
L-curve is defined as the parametric curve:

$$( log {‖ {Ax}_{λ} - b ‖}_{2} , log {‖ {Lx}_{λ} ‖}_{2} ) ;$$

wherein as λ changes, the curve shows a trade-off under different regularization strengths:
for the small λ region: the data fitting residual is small, the solution norm is large, the curve is approximately horizontal, and the residual change is slow;
for the large λ region: the solution norm is small, the residual increases rapidly, the curve is approximately vertical, and the solution norm changes slowly;
for the inflection point region, the curvature is largest at the inflection point that balances data fitting with solution smoothness, corresponding to the optimal λ;
the inflection point corresponds to the point with the largest curvature, wherein calculation steps are as follows:
parameterizing curve: the L-curve is defined as the function η(ρ), wherein

$$ρ = log ‖ {Ax}_{λ} - b ‖$$

$$η = log ‖ {Lx}_{λ} ‖ ;$$

the curvature is calculated:

$$κ ( λ ) = \frac{{ρ}^{′} {η}^{″} - {ρ}^{″} {η}^{′}}{{( {( {ρ}^{′} )}^{2} + {( {η}^{′} )}^{2} )}^{3 / 2}} ;$$

the maximum curvature point is selected: the corresponding λ is the optimal value;
wherein the L-curve criterion is used to achieve the adaptive regularization parameter, the optimal β is selected by the trade-off curve between the data fitting difference Φ_{d} and the model complexity Φₘ, wherein for the generated anisotropic weights, the different λ values are traversed, and the inversion calculation residual and solution norm are executed, finally, the L-curve inflection point is identified to ensure that the inversion model not only fits the data but also maintains the structural characteristics, wherein the initial β is estimated to be:

$${β}_{0} = \frac{{Φ}_{d}}{{( {( {ρ}^{′} )}^{2} + {( {η}^{′} )}^{2} )}^{3 / 2}} ;$$

where Φ_{d} is the difference of data fitting, and the denominator denotes the anisotropic feature of the model complexity;

$${β}_{k + 1} = \frac{{β}_{k}}{γ} ;$$

wherein γ is the cooling factor, βₖ denotes the regularization parameter of the k^{th} iteration, and β is the cooling strategy; the objective of the above setting is to ensure stability with strong regularization (large β) in the initial stage, and gradually reduce it in the later stage to improve the resolution.

The inversion is defined by the RMS between the model response and the measured data:

$$RMS = \sqrt{\frac{{\sum }_{i = 1}^{N} {[ \frac{( {d}_{i}^{o b s} - {d}_{i}^{f w d} )}{{σ}_{i}} ]}^{2}}{N}} ;$$

where

$${d}_{i}^{o b s}$$

denotes i^{th} data,

$${d}_{i}^{f w d}$$

denotes i^{th} data of the forward calculation, σᵢ is the measurement standard deviation of the i^{th} data, and N is the total number of data.
S3: the anisotropic weight stored from the seismic data calculation in step 3 is received through the modular interface, and forms the new regularization term to constrain the inversion;
in step S3, the regularization term generation with seismic data constraint weight includes the following steps:
the projection of the main feature vector in each direction is denoted as:

$$\{ \begin{matrix}{d}_{x} = \vert {V}_{1} \cdot {e}_{x} \vert \\ {d}_{y} = \vert {V}_{1} \cdot {e}_{x} \vert \\ {d}_{z} = \vert {V}_{1} \cdot {e}_{x} \vert\end{matrix} ;$$

the anisotropic strength is:

$$A = 1 - {e}^{- k \frac{{λ}_{1}}{{λ}_{3} + ϵ}} ;$$

a final x-direction weight is:

$${w}_{x} = \{ \begin{matrix}{d}_{x} = 2 ( 1 + {d}_{x} ) & S > {τ}_{coh} \\ {d}_{x} = 0.5 ( 1 - {d}_{x} ) & S < {τ}_{edge} \\ 1 & else\end{matrix} ;$$

where eₓ, e_{y}, and e_{z} denote standard basis vectors (unit vectors in the x, y, and z axes);
for the direction vector v=(a, b, c), the one-direction regularization term decomposition is denoted as:

$${φ}_{v} ( m ) = {α}_{s} {‖ m ‖}^{2} + \frac{a {α}_{x}}{\sum \vert {v}_{i} \vert} {‖ {W}_{x} {\partial }_{x} m ‖}^{2} + \frac{b {α}_{y}}{\sum \vert {v}_{i} \vert} {‖ {W}_{y} {\partial }_{y} m ‖}^{2} + \frac{c {α}_{x}}{\sum \vert {v}_{i} \vert} {‖ {W}_{z} {\partial }_{z} m ‖}^{2} ;$$

where Σ|vᵢ| is the sum of the absolute value of the direction vector, as is the regularization parameter of the model norm, αₓ, α_{y}, and α_{z} denote regularization parameters of gradient terms in the x, y, z directions;

$$\sum \vert {v}_{i} \vert = \vert a \vert + \vert b \vert + \vert c \vert ;$$

anisotropic regularization is formed by summing three orthogonal direction regularization terms:

$${φ}_{m} ( m ) = {φ}_{x} ( m ) + {φ}_{y} ( m ) + {φ}_{z} ( m ) ;$$

where φₘ(m) is the regularization term, and m is the model vector.
S4: the model generation and calculation is performed, and the results of resistivity inversion under the constraint of seismic data are visualized.

### Model Example Calculation

The 3D inversion method of the DC method using seismic data constraints proposed in this solution is based on the maximum principal eigenvector of the structure tensor. In order to verify the effectiveness of the guidance method and the fit degree between 3D Gauss-Newton inversion and 3D data constraint inversion, a simple subsurface 3D model with high resistance and low resistance anomalous bodyies is established in this section and the inversion experiment is performed.

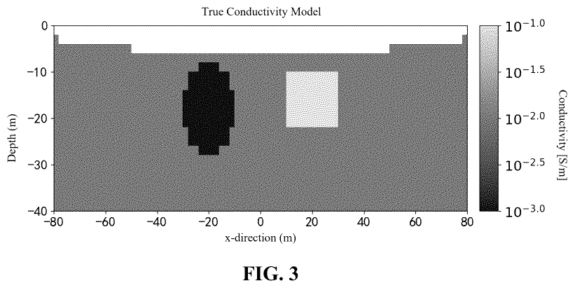

Establishment of resistivity model: firstly, the tests of the present disclosure establish the 3D subsurface uniform half-space resistivity model with high and low resistance anomalous bodies as shown in FIG. 3, to test whether the constraint inversion can accurately restore the target boundary. The surface topography of the model is a basin topography with high surroundings and low middle. The model consists of the high-resistance sphere with a resistivity of 1000 (2·m (purple part) and the low-resistivity region with a resistivity of 10 02.m (yellow part). The resistivity of the subsurface background is 100 Ω·m, and the air resistivity is 10⁸ Ω·m. Furthermore, the model accounts for topographic effects on the forward modeling data, thus removing the air layer above the topography.

The survey network used in the test of this solution includes three survey lines:

Firstly, a main survey line 1 is arranged at y=0, extending in an east-west direction from x=−88 m to 88 m with a length of 176 m, and is configured for surveying the anomalous display of two anomalous bodies on the xoz plane.

Secondly, an auxiliary survey line 2 is arranged at x=−20 m, extending in a north-south direction from y=−88 m to 88 m with a length of 176 m, and is configured for surveying the display of a high-resistance spherical anomalous body.

Finally, an auxiliary survey line 3 is arranged at x=−20 m, extending in a north-south direction from y=−88 m to 88 m with a length of 176 m, and is configured for surveying the display of a low-resistance layered anomalous body.

For the above three survey lines, the device is selected as the dipole-dipole device, with a 1A current source, the electrode distance is set to 12 m, and the number of receivers is set to 6. In order to eliminate the influence of terrain, each electrode is redefined to fall on the terrain, and the modified open source software package SimPEG is used to perform a 3D finite volume numerical simulation, and the received signal data under the 1A current source under the dipole-dipole device is calculated. These data are added to random Gaussian noise with a mean of 0 and a standard deviation of 10% and will be inverted as synthetic data.

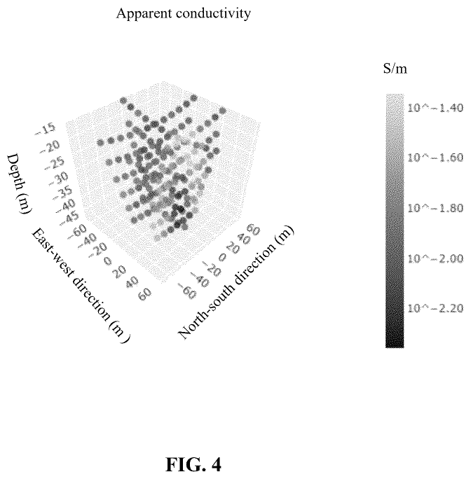

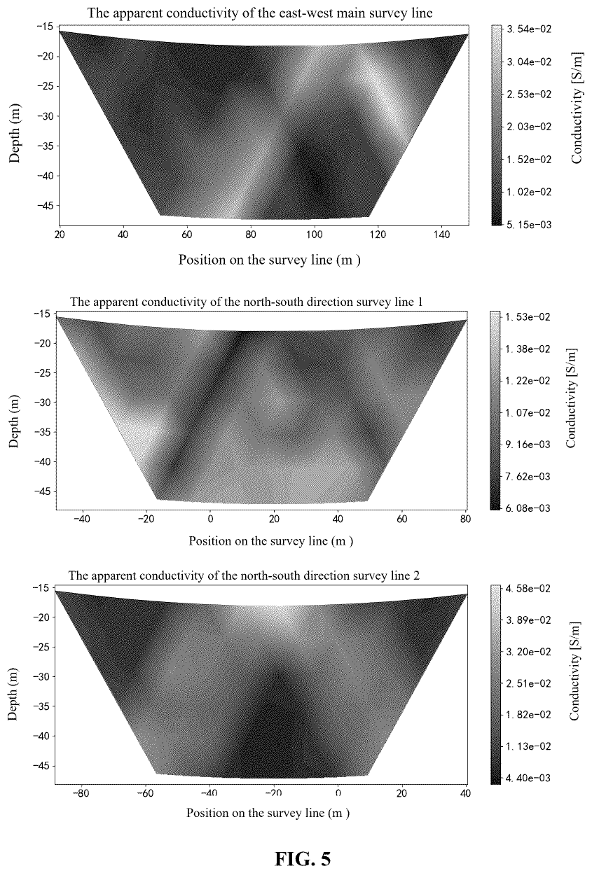

Meanwhile, the above forward line survey data is converted into a 2D cross-sectional view to verify the reliability of the forward data, to generate a forward data visualization part including a 3D pseudo cross-sectional view (FIG. 4), and a 2D cross-sectional view at y=0 and x=+20 (FIG. 5). It can be seen that the high and low resistance anomalies are obviously reflected from the 3D pseudo cross-sectional view and the 2D forward cross-sectional view, and they will not have a great influence on the recognition of multiple targets.

### Establishment of the Velocity Model

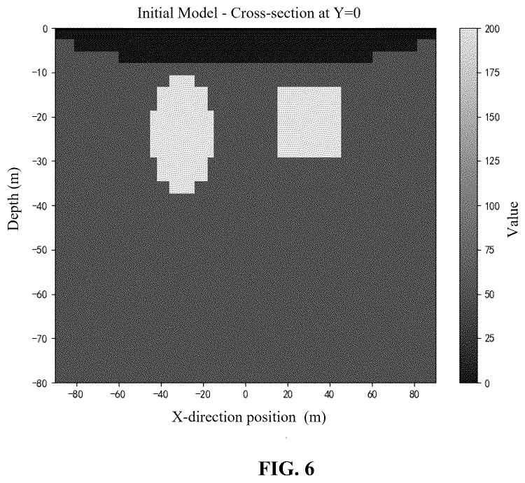

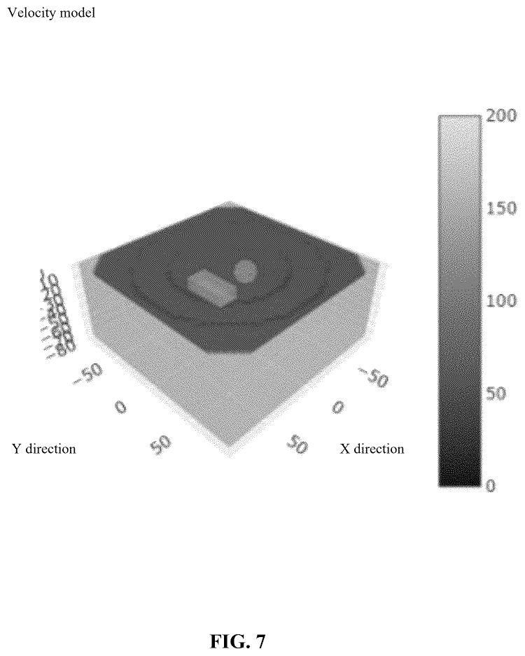

Firstly, the tests of the present disclosure establish a 3D subsurface uniform half-space seismic velocity model containing a high-velocity anomalous body shown in FIG. 6, to test whether constraint inversion can accurately restore the target boundary. The velocity model consists of a high-velocity sphere (purple part) with an interval velocity of 200 m/s and a high-velocity layered cube with an interval velocity of 200 m/s (yellow part). The subsurface background interval velocity is 50 m/s, while considering the influence of terrain on the data, the model removes the air layer above the terrain. In order to verify whether the model is established correctly, a 3D visualization image is shown in FIG. 7 is generated as a guide image for the constraint.

### 3D Gauss-Newton Inversion of Resistivity

In the numerical simulation experiment, since the approximate position of the target is known, in order to reduce the number of grids and improve the grid efficiency, this solution adopts the middle region refinement method in the grid setting to establish a 3D inversion mesh.

A basic cell size is defined as 4 as the reference length for grid partitioning. The x-direction is partitioned into three zones: coarse grid zones on both sides with a cell length of 4, each containing 15 cells; a middle refinement zone with the cell length halved to 2, containing 30 cells, and a total length of 60 cells. The y=direction maintains the same structure as the x-direction, forming symmetrical partitions with identical total length and cell count. The z-direction is divided into two zones: a lower coarse grid zone with a grid length of 4 containing 10 cells and a total length of 40; and an upper refinement zone with a length of 2 containing 20 cells and a total length of 40. After the above refinement and extensive grid generation, a total of 60*60*30=108000 grids are generated. Considering terrain influence, the remaining effective calculation cells after removing the portion above the terrain amount to 100,416.

### Calculation of the Seismic Data Constraint Weights

In this solution, the shown 3D image of the velocity model is regarded as a priori subsurface structure information to guide the inversion of high-density electrical data, and its 3D image visualization is shown in FIG. 6.

The structural tensor field of the 3D image reveals geological structural characteristics of different regions through characteristic ellipsoid shapes and eigenvalues in the 3D model. In homogeneous media regions, all three eigenvalues λ₁, λ₂, and λ₃ approach zero, where the characteristic ellipsoid degenerates into a minute point-like structure near the origin, reflecting the absence of directional variation in these regions. The corresponding code eliminates non-geological interference through an active region mask. In marginal or linear structural regions, the maximum eigenvalue λ substantially exceeds the remaining two eigenvalues, forming a cigar-shaped ellipsoid extending along the principal eigenvector direction, with its major axis perpendicular to the geological interface. Planar structural regions demonstrate similar first two eigenvalues λ₁ and λ₂ that are considerably larger than λ₃, where the ellipsoid compresses into a disk shape with its normal direction perpendicular to the bedding plane. At this stage, the weight generation module enhances constraint strength along the two in-plane directions. Quantitative analysis of the characteristic ellipsoid begins with gradient field computation, where spatial differential information is acquired through Gaussian derivative filtering, followed by construction of a structure tensor matrix containing six independent components. The eigenvalues and eigenvectors extracted after the feature decomposition completely describe the local geometric features.

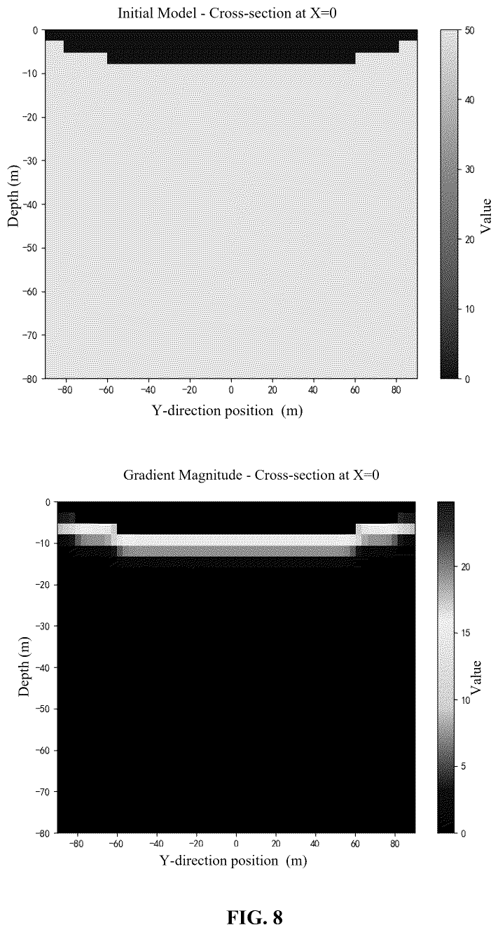

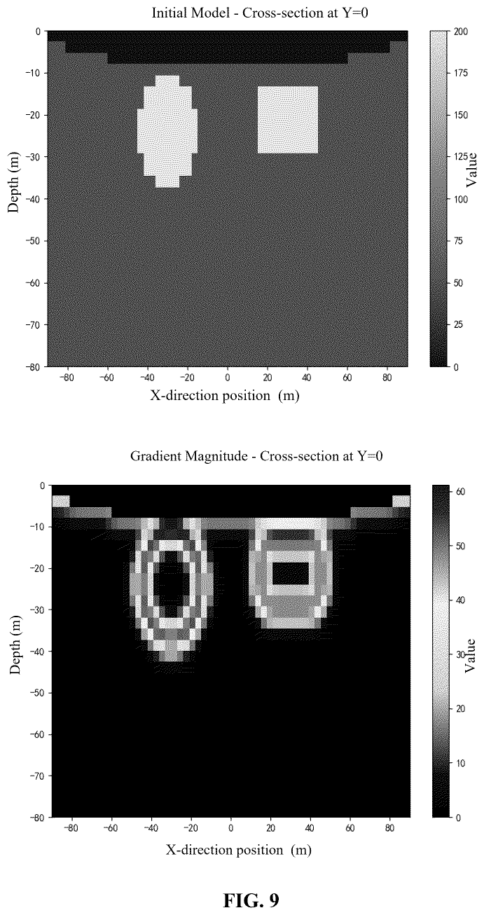

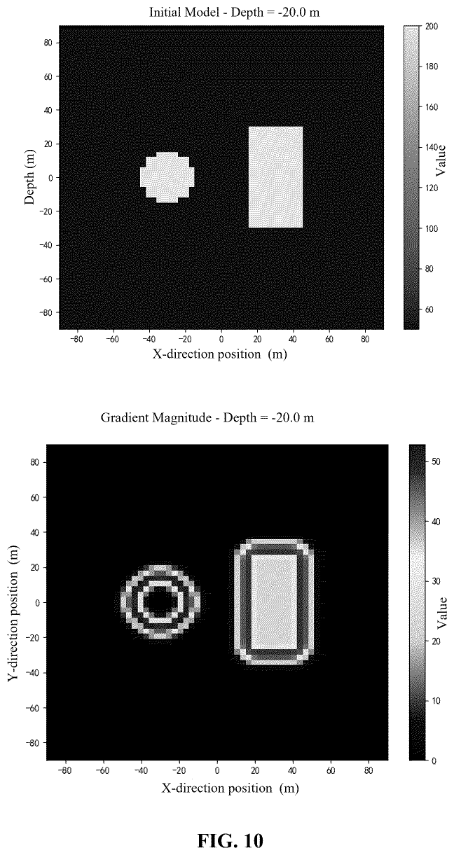

FIGS. 8-10 are cross-sectional comparison diagrams at x=0, y=0 and depth z=−20 m between the model and the maximum principal eigenvalue λ₁ of the guide image, respectively. The eigenvalue is larger at the edge of the target, while the eigenvalue corresponding to the flat region is close to 0, and it is shown as an increasing eigenvalue near the surface in the surface terrain region.

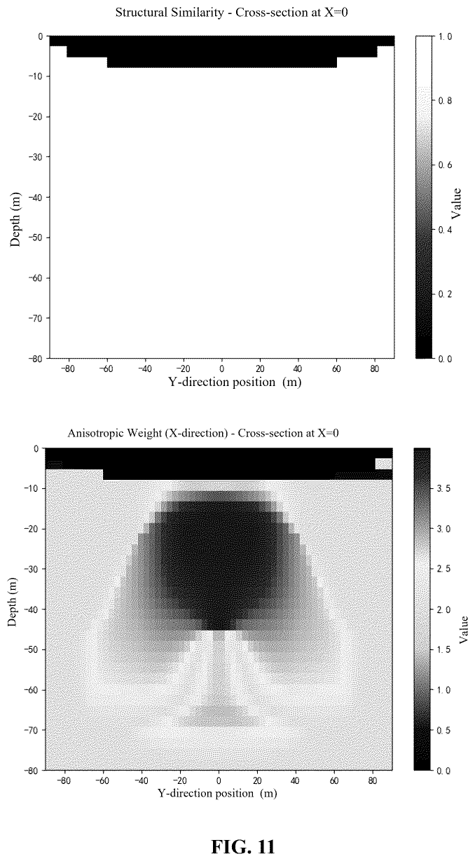

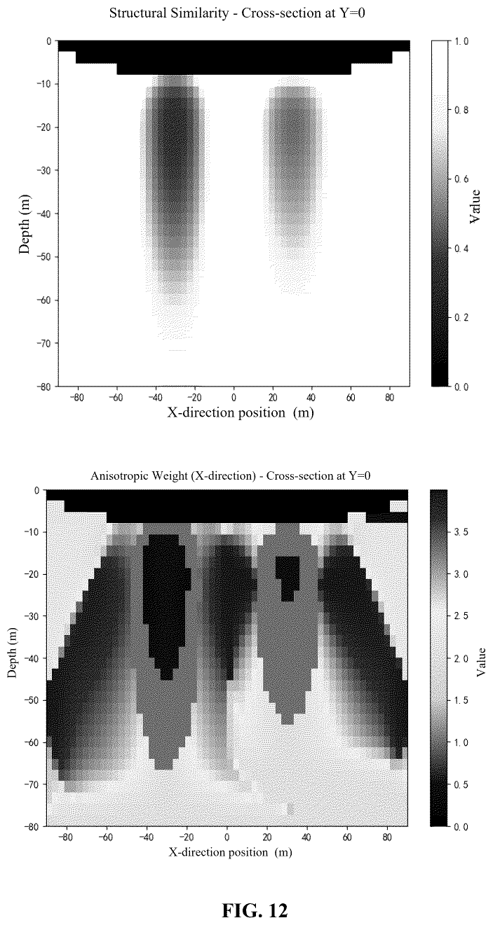

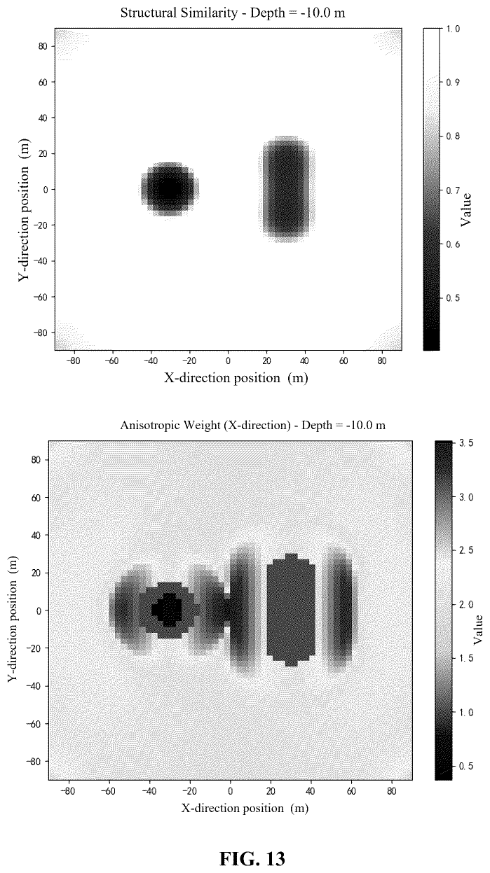

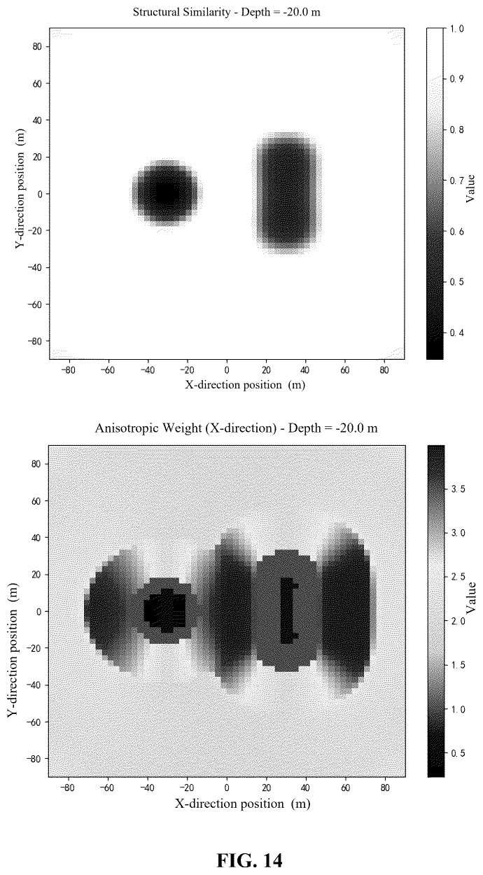

FIGS. 11-14 are cross-sectional views at x=0, y=0, and depth z at =−10 M, −20 m of similarity and anisotropy weight of the guide image, respectively. The similarity and anisotropy weights are calculated by explicit and implicit masks, which avoids the influence of terrain on the calculation.

It can be seen from the figures, the anisotropic weight exhibits an increasing trend from the center to the edge of the target, ultimately reaching a value of 1 in the background region, correlating with effective characterization of both central and edge features of the target. In terms of anisotropic weight performance, the weight coefficients defined by the above weights are given as a=2 and b=0.5. To distinguish the boundary between two targets, the anisotropic weight at the center of the anomalous body gives a small weight, and the anisotropic weight on the boundary of the target well reflects the boundary recognition of the target.

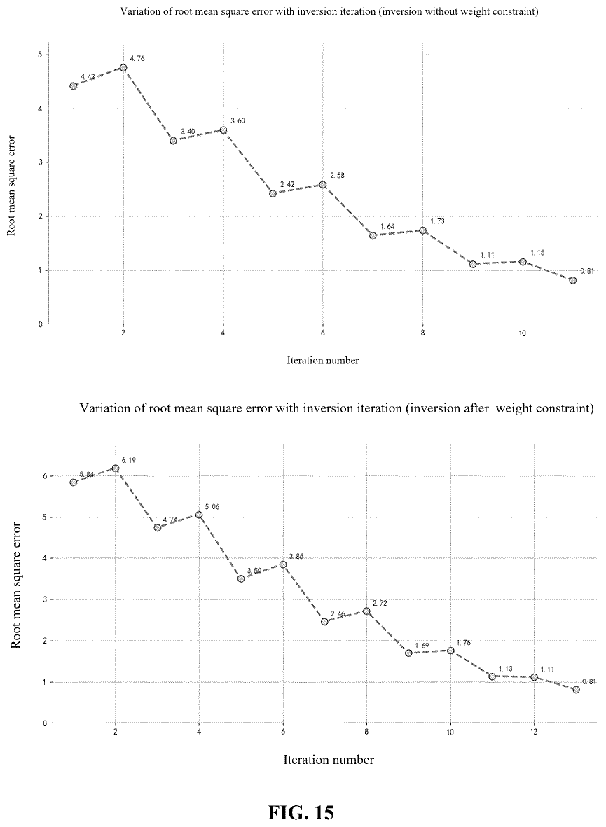

In order to facilitate the comparison of inversion effects, constrained inversion and conventional Gaussian-Newton inversion will employ the same inversion grid. The comparison chart of DRMS with the number of inversion iterations is shown in FIG. 15. It can be seen that the DRMS of both inversions fluctuates to within one percent to reach the convergence condition. The number of inversion iterations of constrained inversion is more than that of conventional inversion, but the convergence time of constrained inversion is slightly faster than that of conventional inversion.

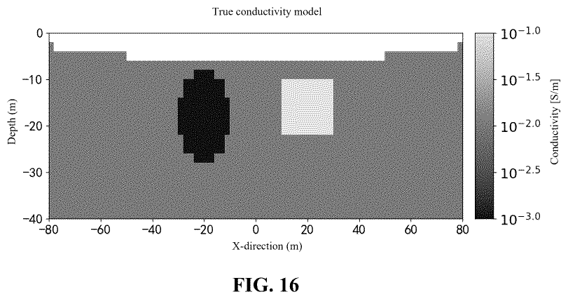

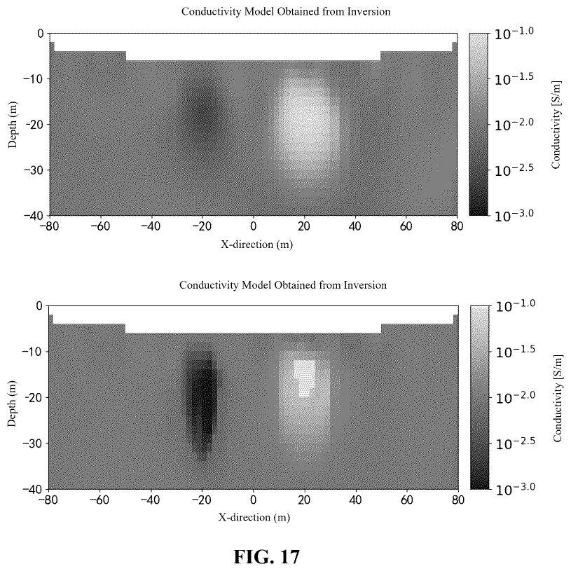

The comparison between Gauss-Newton inversion and image-guided inversion results and the correct model at the y=0 interface is shown in FIGS. 16-17. Compared with the single method inversion results generated by conventional Gauss-Newton inversion, the 3D image-guided inversion more clearly depicts two targets and is reliable for the identification of multiple targets. Furthermore, based on the internal high-resistivity/low-resistivity morphology and extension of the two targets, the characterization of both the centers and boundaries of the high-resistivity bodies proves accurate, and vertical resolution is improved; compared with conventional inversion, the characterization of the center and upper/lower boundaries of the low-resistivity body is more accurate and basically consistent with the true model.

### Embodiment 1

The method and software of this solution can be applied to 3D accurate inversion of geophysical exploration. The scope of the application can be divided into two parts: the theoretical application field and the engineering application field, as follows:

### Theoretical Applications:

1. Multi-source geophysical data fusion theory: this algorithm provides a novel theoretical framework for geophysical joint inversion. By introducing the seismic velocity structure tensor to construct anisotropic regularization constraints, the mathematical physical model of electrical method-seismic data collaborative inversion is established, which promotes the development of multi-method data fusion theory.
2. Optimization of 3D inversion algorithm: the provided finite volume method-Gauss-Newton hybrid solution framework, GPU-accelerated structure tensor calculation and adaptive regularization parameter strategy can be extended to other geophysical inversion fields such as electromagnetic method and gravity to improve computational efficiency and stability of complex models.
3. Structural constraint inversion theory: through the directional coupling of seismic image feature extraction and electrical model, it provides a novel idea for solving the multiple solutions of single method inversion, particularly suitable for the fine representation of structural features such as layered media and fault boundaries.

Engineering applications: compatible with SimPEG standard input formats (Survey, Mesh), support seamless connection with existing electrical methods and seismic processing processes (such as ResIPy, SeisPy), and reduce user migration costs; compatible with the terrain correction module, it achieves joint modeling of seismic-electrical data under undulating surface conditions through the mesh deformation interface (Mesh. TensorMesh), and solves the limitations of the default flat terrain assumption.
1. Mineral resources exploration: suitable for accurate imaging of 3D electrical structures of metal ore bodies and oil and gas reservoirs. It can be combined with seismic velocity model constraints to improve ore body boundary identification capabilities and reduce drilling verification costs. For example, in skarn deposits, the mineralized alteration zone can be effectively delineated by the joint analysis of resistivity anomaly and seismic velocity sudden change.
2. Hydrogeological survey: configured for the spatial distribution of aquifers and the fine characterization of groundwater pollution plume boundaries. Combined with seismic reflection interface constraints, it can distinguish the contact relationship between low-resistance aquifers and high-resistance bedrocks and improve the accuracy of water resources assessment.
3. Engineering geological exploration:
Tunnel and subsurface engineering: the geological hazards such as karst pipelines and fault zones can be identified, the longitudinal resolution of resistivity inversion is enhanced through seismic horizon constraints, and assistance in engineering geological stratification is provided.

Dam foundation and slope stability: detection of weak interlayers and seepage channels is performed, and the combination with the anisotropic characteristics of seismic velocity is utilized to achieve integrity evaluation of rock mass.
4. Environmental and disaster geology:
Detection of contaminated sites: the diffusion range of pollutants is defined, seismic interface constraints are used to distinguish artificial fill from primary strata, and the vertical positioning accuracy of pollution boundaries can be improved.

Goaf and earth fissures: through the spatial coupling of resistivity anomalies and seismic wave rapid descent regions, subsurface cavities and rock formation dislocation zones can be accurately identified.
5. Urban subsurface space development: suitable for the detection of shallow electrical structures such as subway tunnels and pipe corridors. Combined with seismic profile data constraints, the interface between artificial structures and natural strata can be effectively distinguished, and the impact of urban noise interference can be mitigated.

Therefore, the present disclosure employs the abovementioned 3D inversion method of DC method using seismic data constraints, which applies seismic data constraints to 3D resistivity inversion, performs numerical simulation and inversion of electrical data under undulating terrain using the finite volume method and Gauss-Newton inversion method. Furthermore, the seismic anisotropic velocity tensor constraint is introduced for inversion to mitigate the non-uniqueness inherent in single-method inversion, yielding a more accurate 3D subsurface electrical structure and improving the resolution of longitudinal boundaries.

Finally, it should be noted that the above embodiments are merely used for describing the technical solutions of the present disclosure, rather than limiting the same. Although the present disclosure has been described in detail with reference to the preferred examples, those of ordinary skill in the art should understand that the technical solutions of the present disclosure may still be modified or equivalently replaced. However, these modifications or substitutions should not make the modified technical solutions deviate from the spirit and scope of the technical solutions of the present disclosure.

What is claimed is:

1. A three-dimensional (3D) inversion method of a direct current (DC) method using seismic data constraints, comprising a processing of seismic data and an inversion of resistivity data;
wherein the processing of the seismic data comprises the following steps:
step 1: processing 3D seismic velocity data or a 3D seismic image related to electric exploration data, removing an air layer part, performing a calculation of a structure tensor to obtain structure tensor data, and accelerating a calculation of the structure tensor and eigendecomposition through a hybrid calculation of a graphics processing unit (GPU) and a central processing unit (CPU);
step 2: adopting a multi-scale Gaussian filtering method, constructing weight data through correlation determinations, solving problems of fuzzy terrain boundary and invalid region interference of a geological model by a mask processing method, thereby providing input data for anisotropic inversion; and
step 3: calculating and defining an anisotropy coefficient with reference to a structural feature of the correlation by an eigenvalue ratio corresponding to a main feature direction and a normal feature direction, and simultaneously outputting a storage and a visualization of anisotropy weight in a modular form;
wherein the processing of the inversion of resistivity data comprises the following steps:
S1: performing a calculation by adopting a finite volume method, discretizing a calculation region into non-overlapping control volumes or control voxels, applying conservation equations to integrate the control volumes, obtaining a set of discrete equations by discretizing the integral equations, and obtaining required apparent resistivity by solving the discrete equations;
S2: obtaining resistivity inversion under seismic data constraint by updating a framework of Gauss-Newton inversion, solving a linear system by a preconditioned conjugate gradient (PCG) method, performing an inversion with an adaptive regularization parameter guided by a L-curve criterion, and evaluating an inversion effect by using a root mean square error;
S3: receiving the anisotropic weight stored from the seismic data calculation in step 3 through a modular interface, and forming a new regularization term to constrain the inversion; and
S4: performing a model generation and calculation, and visualizing results of resistivity inversion under the constraint of seismic data.

2. The 3D inversion method of the DC method using seismic data constraints according to claim 1, wherein in step 1, a calculation method of structure tensor data is as follows:
calculating a gradient field by using a central difference combined with a Gaussian derivative kernel, and a 3D discrete gradient operator is defined as:
$$\{ \begin{matrix}{I}_{x} [ i , j , k ] = \frac{I [ i + 1 , j , k ] - I [ i - 1 , j , k ]}{2 Δ x} \\ {I}_{y} [ i , j , k ] = \frac{I [ i , j + 1 , k ] - I [ i , j - 1 , k ]}{2 Δ y} \\ {I}_{z} [ i , j , k ] = \frac{I [ i , j , k + 1 ] - I [ i , j , k - 1 ]}{2 Δ z}\end{matrix} ;$$
eliminating a high-frequency noise by Gaussian smoothing:
$$= {G}_{σ} * {I}_{x} , = {G}_{z} * {I}_{z} , = {G}_{σ} * {I}_{z} ;$$
a discrete form of Gaussian kernel G, is:
$${G}_{σ} [ n ] = \frac{1}{{( 2 π )}^{1 / 2} σ} {e}^{\frac{{n}^{2}}{2 {σ}^{2}}} ;$$
wherein the structure tensor is a second-order tensor matrix derived from a gradient, and a mathematical form of the 3D structure tensor is:
$${S}_{σ} = {G}_{σ} * [ \begin{matrix}{I}_{x}^{2} & {I}_{x} {I}_{y} & {I}_{x} {I}_{z} \\ {I}_{x} {I}_{y} & {I}_{y}^{2} & {I}_{y} {I}_{z} \\ {I}_{x} {I}_{z} & {I}_{y} {I}_{z} & {I}_{z}^{2}\end{matrix} ] = [ \begin{matrix}{S}_{xx} & {S}_{xy} & {S}_{xz} \\ {S}_{xy} & {S}_{yy} & {S}_{yz} \\ {S}_{xz} & {S}_{yz} & {S}_{zz}\end{matrix} ] ;$$
where Iₓ, I_{y} and I_{z} are gradients in each direction, S_{σ} is a structure tensor matrix corresponding to a node (i,j,k), *is a convolution operator, G_{σ} is a two-dimensional Gaussian difference operator, and σ controls a Gaussian function;
wherein an expression of the Gaussian difference operator is:
$${G}_{σ} ( x , y , z ) = \frac{1}{{( 2 π σ )}^{3 / 2} {G}_{x} {G}_{y} {G}_{z}} {e}^{- ( \frac{{x}^{2}}{2 {σ}_{x}^{2}} + \frac{{y}^{2}}{2 {σ}_{y}^{2}} + \frac{{z}^{2}}{2 {σ}_{z}^{2}} )} ;$$
$${S}_{σ} = {λ}_{1} {ν}_{1} {ν}_{1}^{T} + {λ}_{2} {ν}_{2} {ν}_{2}^{T} + {λ}_{3} {ν}_{3} {ν}_{3}^{T} ( {λ}_{1} > {λ}_{2} > {λ}_{3} ) ;$$
the structure tensor matrix S_{σ} is a 3×3 real matrix, which is decomposed into three eigenvalues (λ₁,λ₂,λ₃) and three pairwise orthogonal eigenvectors (v₁,v₂,v₃), wherein the eigenvector v₁ corresponding to a largest eigenvalue denotes a direction pointing to a maximum local gradient energy, which is perpendicular to a structural boundary;
wherein in a continuous medium, v₁ is perpendicular to a formation interface; in a sharp edge, v₁ is perpendicular to a fault surface; the second eigenvector v₂ is in a plane orthogonal to v₁, which denotes a secondary change direction of a local structure, the third eigenvector v₃ points to a direction with a minimum local change, which is typically parallel to a main extension direction of the structure, λ₁>>λ₃, denoteing strong anisotropy; λ₁≈λ₃, denoteing isotropy.

3. The 3D inversion method of the DC method using seismic data constraints according to claim 2, wherein in step 1, the accelerating the calculation of the structure tensor and eigendecomposition through the hybrid calculation of the GPU and CPU is performed on a hardware environment with a graphics card, and a calculation process is as follows:
1.1: migrating velocity model data from host memory to video memory of the graphics card through an asynchronous transmission channel of a CuPy library, and achieving a zero-copy data interaction between CPU and GPU by using a unified memory architecture of CUDA8.0;
1.2: utilizing a parallelized 3D central difference method for a gradient computation, with compute unified device architecture (CUDA) thread blocks handling differential operations on 32×32×32 voxel regions, and employing shared memory caching of local data to reduce global memory access latency; and
1.3: during a construction process of the structure tensor, mapping calculations of six independent components (Txx, Txy, Txz, Tyy, Tyz, and Tzz) to different streaming multiprocessors (SM) for a parallel execution, vectorizing element-wise operations corresponding to the components through a broadcast mechanism of GPU, and utilizing separable convolution characteristics of Gaussian filter to decompose the 3D convolution into a cascade of three one-dimensional (1D) convolutions.

4. The 3D inversion method of the DC method using seismic data constraints according to claim 3, wherein in step 2, a similarity S is calculated by defining the Gaussian filters S₁ and S₂ of transverse structures and longitudinal structures, wherein a diffusion tensor D is determined by a feature vector and weight:
$$\frac{\partial m}{\partial t} = ∇ \cdot ( D ∇ m ) ;$$
wherein the similarity S is defined as:
$$S = \frac{{S}_{2}}{{S}_{1} + ϵ} ;$$
wherein a calculation of S₁ is divided into the following three steps, wherein a response of a horizontal continuous structure is enhanced by a transverse-priority filtering strategy:
(1) performing a transverse Gaussian filtering along an x-y plane, wherein the anisotropic Gaussian kernel is shown as follows:
$$\begin{matrix}{I}_{temp 1} = {G}_{{σ}_{1}} * I \\ {σ}_{1} = ( 2 , 2 , 0 )\end{matrix} ;$$
here σₓ=σ_{y}=2, σ_{z}=0, which denotes only smoothing in the x-y plane;
(2) performing a longitudinal Gaussian filtering along a z direction:
$$\begin{matrix}{I}_{temp 2} = {G}_{2} * {I}_{temp 1} \\ {σ}_{2} = ( 0 , 0 , 8 )\end{matrix} ;$$
here σₓ=σ_{y}=0, σ_{z}=8, which denotes filtering along the z direction;
(3) final smoothing:
$$\begin{matrix}{S}_{1} = {G}_{{σ}_{3}} * ( {I}_{temp 1} ⊙ {I}_{temp 2} ) \\ {σ}_{3} = 2\end{matrix} ;$$
where ⊙ denotes a multiplication of corresponding position elements of the matrix; wherein I is 3D image data, with a dimension of (x, y, z); σ₁ is a Gaussian kernel parameter of (σₓ=2, σ_{y}=2,), G_{σ}_{₁} is a 3D Gaussian filter with σ₁ as the parameter, only filtering in the x and y directions, and maintaining an original value in the z direction; and G_{σ}_{₃} is a 3D isotropic Gaussian filter for (σₓ=2, σ_{y}=2,), smoothing in all directions;
wherein a calculation of S₂ is divided into the following three steps, wherein a response of the vertical continuous structure is enhanced by a longitudinal-priority filtering strategy:
\textcircled{1} performing a longitudinal Gaussian filtering along a y=z plane:
$$\begin{matrix}{I}_{temp 3} = {G}_{{σ}_{4}} * I \\ {σ}_{4} = ( 0 , 8 , 8 )\end{matrix} ;$$
here σ_{y}=σ_{z}=8, σₓ=0, which denotes only smoothing in the y=z plane;
(2) performing a transverse Gaussian filtering along an x direction:
$$\begin{matrix}{I}_{temp 4} = {G}_{5} * {I}_{temp 3} \\ {σ}_{5} = ( 2 , 0 , 0 )\end{matrix} ;$$
here σ_{y}=σ_{z}=0, σₓ=2, which denotes filtering along the x direction;
(3) final smoothing:
$$\begin{matrix}{S}_{2} = {G}_{{σ}_{6}} * ( {I}_{temp 3} ⊙ {I}_{temp 4} ) \\ {σ}_{6} = 8\end{matrix} ;$$
where ⊙ denotes a multiplication of corresponding position elements of the matrix.

5. The 3D inversion method of the DC method using seismic data constraints according to claim 4, wherein in the mask processing process of step 2, an essence of the mask is a binary matrix, configured to mark valid regions of data space, mathematically expressed as:
$$M ( x ) = \{ \begin{matrix}1 , & x ∈ valid region \\ 0 , & x ∈ invalid region\end{matrix} ;$$
where M(x) denotes a spatial position-dependent binary matrix, configured to selectively retain or suppress data by performing an element-wise multiplication:
$${D}_{masked} = D ⊙ M ;$$
where D is an original data matrix, M is denoted as a binary matrix generated by the function M(x), which is the same as a dimension of the original data matrix D, and D_{masked} denotes a result of the selective retention of the original data D through the mask matrix M;
wherein a calculation of introducing a mask in the gradient calculation is:
$$∇ {I}_{masked} = ∇ I ⊙ M ;$$
wherein a dynamic mask is introduced in a structural similarity calculation, and the boundary is kept clear through multiple applications of the mask, and a calculation is:
an initial data mask:
$${D}_{0} = D ⊙ M ;$$
a gaussian filter mask:
$${D}_{1} = {G}_{σ} ( {D}_{0} ) ;$$
a secondary mask:
$${{D}_{2}}^{masked} = {D}_{1} ⊙ M .$$

6. The 3D inversion method of the DC method using seismic data constraints according to claim 5, wherein in step 3, a process of anisotropy and weight calculation is as follows:
calculating and defining an anisotropy coefficient by an eigenvalue ratio corresponding to a main feature direction and a normal feature direction:
$${λ}_{r} = \frac{{λ}_{1}}{{λ}_{3} + ϵ} ;$$
$$α = 1 - {e}^{- k {λ}_{r}} ;$$
where k is a positive real number, configured to adjust an influence of an eigenvalue ratio λᵣ on the anisotropy coefficient, k→0: wherein the anisotropy effect almost disappears, and the model degenerates into isotropic smoothing, wherein a larger k results in more sensitive regional response; a smaller k weakens anisotropic differences, and a value of k is [0.5,2.0].
obtaining weight values of the following three constraints based on the determination of the calculated similarity;
when the similarity S is less than a value of a boundary determination condition, it is determined as an edge region, and a smoothing intensity is reduced in the edge region, and a sharp boundary is retained; wherein a value edge_threshold of the boundary determination condition is set to a constant;
when the similarity S is greater than a value of a coherence determination condition, it is determined as a structurally coherent region, and smoothing along the main direction is enhanced in a coherent region to suppress noise; wherein a value coherence_threshold of the coherence determination condition is set to a constant;
other parts are set to 1:
$$ω = \{ \begin{matrix}a ( 1 + α ) & S > coherence\_threshold \\ b ( 1 - α ) & S < edge\_threshold \\ 1 & otherwise\end{matrix} ;$$
wherein input data of weight calculation has been preprocessed by the mask, and anisotropic weight after mask processing is expressed as:
$$W ( x ) = f ( ∇ {I}_{masked} , {λ}_{i} , {v}_{i} ) \cdot M ( x ) ;$$
where ƒ is a weight calculation method, λᵢ and vᵢ are an eigenvalue and an eigenvector of the structure tensor, respectively, and a and b are given weight coefficients.

7. The 3D inversion method of DC method using seismic data constraints according to claim 6, wherein in S1, according to a theory of finite volume method, a control volume of a unit where a node (i, j, k) is located is recorded as V_{i,j,k}, and a discrete source term of a control equation in the control volume is:
$$∇ \cdot ( σ ∇ u ) = - s ;$$
where u denotes a potential, σ denotes a conductivity of a medium, and −s is defined as a source term denoting current injection or reception per unit volume;
performing a volume integral of the above equation in the control volume:
$$\frac{1}{\vert {V}_{i , j , k} \vert} {\int }_{{V}_{i , j , k}} ∇ \cdot ( σ ∇ u ) dV = - \frac{1}{\vert {V}_{i , j , k} \vert} {\int }_{{V}_{i , j , k}} s dV ;$$
applying the Gauss theorem to the left side expression to obtain:
$$\frac{1}{\vert {V}_{i , j , k} \vert} {\int }_{{V}_{i , j , k}} ∇ \cdot ( σ ∇ u ) dV = \frac{1}{\vert {V}_{i , j , k} \vert} {\int }_{\partial {V}_{i , j , k}} ( σ ∇ u ) \cdot n dS ;$$
wherein in the control volume, V_{i,j,k} denotes a volume, ∂V_{i,j,k} is a surface area, and performing surface integration and simplification on the right side expression to obtain:
$${\int }_{\partial {V}_{i , j , k}} ( σ ∇ u ) \cdot n dS = {\int }_{{S}_{i + \frac{1}{2}}} σ ∇ u dS - {\int }_{{S}_{i - \frac{1}{2}}} σ ∇ u dS + {\int }_{{S}_{j + \frac{1}{2}}} σ ∇ u dS - {\int }_{{S}_{j - \frac{1}{2}}} σ ∇ u dS + {\int }_{{S}_{k + \frac{1}{2}}} σ ∇ u dS - {\int }_{{S}_{k - \frac{1}{2}}} σ ∇ u dS ;$$
$$since {S}_{i + \frac{1}{2}} = {S}_{i - \frac{1}{2}} , {S}_{j + \frac{1}{2}} = {S}_{j - \frac{1}{2}} , and$$
$${S}_{k + \frac{1}{2}} = {S}_{k - \frac{1}{2}} , further simplifying to obtain :$$
$$\frac{1}{\vert {V}_{i , j , k} \vert} {\int }_{\partial {V}_{i , j , k}} ( σ ∇ u ) \cdot n dS = \frac{{( σ \frac{\partial u}{\partial x} )}_{i + \frac{1}{2} , j , k} - {( σ \frac{\partial u}{\partial x} )}_{i - \frac{1}{2} , j , k}}{{h}_{i}^{x}} + \frac{{( σ \frac{\partial u}{\partial y} )}_{i , j + \frac{1}{2} , k} - {( σ \frac{\partial u}{\partial y} )}_{i , j - \frac{1}{2} , k}}{{h}_{i}^{y}} + \frac{{( σ \frac{\partial u}{\partial z} )}_{i , j , k + \frac{1}{2}} - {( σ \frac{\partial u}{\partial z} )}_{i , j , k - \frac{1}{2}}}{{h}_{i}^{z}} ;$$
$${h}_{i}^{x} , {h}_{i}^{y} , and {h}_{i}^{z}$$
are lengths of the control volume in the x, y, and z directions, respectively, wherein
$${( σ \frac{\partial u}{\partial x} )}_{i + \frac{1}{2} , j , k}$$
is expressed as:
$${( σ \frac{\partial u}{\partial x} )}_{i + \frac{1}{2} , j , k} = {{σ}_{i + \frac{1}{2} , j , k} ( \frac{\partial u}{\partial x} )}_{i + \frac{1}{2} , j , k} ;$$
$${σ}_{i + \frac{1}{2} , j , k}$$
is a harmonic mean of the two control volumes of the conductivity in the x direction:
$${σ}_{i + \frac{1}{2} , j , k} = {{h}_{i + \frac{1}{2}}^{x} ( {\int }_{{x}_{i}}^{{x}_{i + 1}} {σ}^{- 1} ( x , y , z ) dx )}^{- 1} ;$$
in the above equation:
$${h}_{i + \frac{1}{2}}^{x} = {x}_{i + 1} - {x}_{i} = ( {h}_{i + 1}^{x} + {h}_{i}^{x} ) / 2 ;$$
thus:
$${( σ \frac{\partial u}{\partial x} )}_{i + \frac{1}{2} , j , k} = {{h}_{i + \frac{1}{2}}^{x} ( \frac{{h}_{i}^{x}}{2 {σ}_{i , j , k}} + \frac{{h}_{i + 1}^{x}}{2 {σ}_{i + 1 , j , k}} )}^{- 1} ( \frac{{u}_{i + 1 , j , k} - {u}_{i , j , k}}{{h}_{i + \frac{1}{2}}^{x}} ) ;$$
$${( σ \frac{\partial u}{\partial x} )}_{i - \frac{1}{2} , j , k} = {{h}_{i + \frac{1}{2}}^{x} ( \frac{{h}_{i}^{x}}{2 {σ}_{i , j , k}} + \frac{{h}_{i - 1}^{x}}{2 {σ}_{i - 1 , j , k}} )}^{- 1} ( \frac{{u}_{i , j , k} - {u}_{i - 1 , j , k}}{{h}_{i - \frac{1}{2}}^{x}} ) ;$$
$$\frac{1}{\vert {V}_{i , j , k} \vert} {\int }_{\partial {V}_{i , j , k}} ( σ ∇ u ) \cdot n dS = \frac{{σ}_{i + \frac{1}{2} , j , k} ( \frac{{u}_{i + 1 , j , k} - {u}_{i , j , k}}{{h}_{i + \frac{1}{2}}^{x}} ) - {σ}_{i - \frac{1}{2} , j , k} ( \frac{{u}_{i , j , k} - {u}_{i - 1 , j , k}}{{h}_{i - \frac{1}{2}}^{x}} )}{{h}_{i}^{x}} + \frac{{σ}_{i , j + \frac{1}{2} , k} ( \frac{{u}_{i , j + 1 , k} - {u}_{i , j , k}}{{h}_{j + \frac{1}{2}}^{y}} ) - {σ}_{i , j - \frac{1}{2} , k} ( \frac{{u}_{i , j , k} - {u}_{i , j - 1 , k}}{{h}_{j - \frac{1}{2}}^{y}} )}{{h}_{i}^{y}} + \frac{{σ}_{i , j , k + \frac{1}{2}} ( \frac{{u}_{i , j , k + 1} - {u}_{i , j , k}}{{h}_{k + \frac{1}{2}}^{z}} ) - {σ}_{i , j , k - \frac{1}{2}} ( \frac{{u}_{i , j , k} - {u}_{i , j , k - 1}}{{h}_{k - \frac{1}{2}}^{z}} )}{{h}_{i}^{z}} = - \frac{1}{\vert {V}_{i , j , k} \vert} {\int }_{{V}_{i , j , k}} s dV ;$$
wherein the source term is:
$$\frac{1}{\vert {V}_{i , j , k} \vert} {\int }_{{V}_{i , j , k}} s dV = \{ \begin{matrix}I & ( {x}_{a} , {y}_{a} , {z}_{a} ) ∈ {V}_{i , j , k} \\ 0 & ( {x}_{a} , {y}_{a} , {z}_{a} ) ∉ {V}_{i , j , k}\end{matrix} .$$

8. The 3D inversion method of DC method using seismic data constraints according to claim 7, wherein in S₂, a core of the Gauss-Newton inversion method is to perform a first-order Taylor expansion to a nonlinear forward response F(m), wherein a current model is mₖ,
$$F ( {m}_{k + 1} ) = F ( {m}_{k} ) + {J}_{k} ( {m}_{k + 1} - {m}_{k} ) ;$$
where Jₖ is a Jacobian matrix, the element is denoted by:
$${J}_{i j} = \frac{\partial {F}_{i}}{d {m}_{j}} ;$$
where Fᵢ is denoted as an i^{th} forward response, m; denotes a j^{th} model parameter, and Jᵢⱼ is a partial derivative of an i^{th} observation data to the j^{th} model parameter;
wherein an updated approximate objective function is:
$$Φ ( {m}_{k + 1} ) = \frac{1}{2} {‖ {W}_{d} ( d - F ( {m}_{k} ) - {W}_{d} {J}_{k} ( {m}_{k + 1} - {m}_{k} ) ) ‖}^{2} + \frac{β}{2} {‖ {W}_{m} ( {m}_{k + 1} - {m}_{r e f} ) ‖}^{2} ;$$
where W_{d} is a data-weighting matrix for the measured data;
computing a derivative of Φ(mₖ₊₁) with respect to mₖ₊₁ and setting the derivative to zero, to obtain a linear system:
$$( {J}_{k}^{T} {W}_{d}^{T} {W}_{d} {J}_{k} + β {W}_{m}^{T} {W}_{m} ) ( {m}_{k + 1} - {m}_{k} ) = {J}_{k}^{T} {W}_{d}^{T} {W}_{d} ( d - F ( {m}_{k} ) ) - β {W}_{m}^{T} {W}_{m} ( {m}_{k} - {m}_{k + 1} ) ;$$
wherein a model update equation is:
$${m}_{k + 1} = {m}_{k} + αδ m ;$$
$$wherein : δ m = {( {J}_{k}^{T} {W}_{d}^{T} {W}_{d} {J}_{k} + β {W}_{m}^{T} {W}_{m} )}^{- 1} ;$$
the resulting linear system is solved by a preconditioned conjugate gradient method (PCG), which is a conjugate gradient (CG) method combined with a precondition:
initializing parameters by setting an initial model update to zero, and an initial residual is equal to a gradient vector:
$$\begin{matrix}δ {m}_{0} = 0 \\ {r}_{0} = g - H δ {m}_{0}\end{matrix} ;$$
where g denotes a gradient vector, and H denotes a Hessian matrix;
accelerating convergence by applying a preconditioned matrix M to residual; and
setting an initial search direction as the preconditioned residual:
$$\begin{matrix}{z}_{0} = {M}^{- 1} {r}_{0} \\ {p}_{0} = {z}_{0}\end{matrix} ;$$
where z₀ denotes a preconditioned residual, r₀ denotes an initial residual, and p₀ denotes an initial search direction,
an iteratively updated step size αₖ is calculated by minimizing a quadratic function ƒ(δm):
$$f ( δ m ) = \frac{1}{2} ( δ {m}^{T} H δ m - {g}^{T} δ m ) ;$$
wherein
$$\frac{\partial f}{\partial α} = 0$$
is satisfied at a minimum point along direction pₖ, and a step size αₖ is obtained:
$${α}_{k} = \frac{{r}_{k}^{T} {z}_{k}}{{p}_{k}^{T} {Hp}_{k}} ;$$
wherein a molecule is an inner product of the preconditioned residual, configured to measure current residual energy; rₖ denotes a residual of a k^{th} iteration; zₖ denotes a preconditioned residual, to adjust a distribution of the residual through the preconditioned matrix M, thus improving a condition number of the linear system, and accelerating the convergence; a denominator is an energy of the search direction under the Hessian metric, and pₖ denotes a search direction of the k^{th} iteration;
wherein subsequent model updates and residual updates are:
$$δ {m}_{k + 1} = δ {m}_{k} + {α}_{k} {P}_{k} ;$$
$${r}_{k + 1} = {r}_{k} - {α}_{k} {P}_{k} ;$$
stepping αₖ along the search direction, updating the model correction; applying preconditions and calculating new directions, processing a new residual by the preconditioner, and eliminating an ill-conditionality of the Hessian matrix:
$${z}_{k + 1} = {M}^{- 1} {r}_{k + 1} ;$$
updating βₖ to measure an old and new residual energy ratio, and adjusting the search direction to obtain:
$${β}_{k} = \frac{{r}_{k + 1}^{T} {z}_{k + 1}}{{r}_{k}^{T} {z}_{k}} ;$$
generating a conjugate direction by combining the current preconditioned residual with the previous direction:
$${p}_{k + 1} = {z}_{k + 1} + {β}_{k} {p}_{k} ;$$
where βₖ denotes an adjustment coefficient of the conjugate direction;
setting a termination condition to terminate the iteration when a residual norm is reduced to 1% of the initial residual to balance a computational efficiency and an accuracy, thus avoiding excessive iterations:
$$\frac{‖ {r}_{k} ‖}{‖ g ‖} < t o lCG ;$$
where ∥g∥ denotes a norm of the initial residual r₀=g, configured as a convergence benchmark.

9. The 3D inversion method of the DC method using seismic data constraints according to claim 8, wherein in S2, in the process of the adaptive regularization, a L-curve criterion is used to determine an optimal value of regularization parameter, and an objective function of regularization problem can be defined as:
$${min}_{x} \{ {‖ Ax - b ‖}_{2}^{2} + {λ}^{2} {‖ Lx ‖}_{2}^{2} \} ;$$
wherein A is a coefficient matrix, b is an observation data; L is a regularization matrix, and λ is a regularization parameter;
wherein L-curve is defined as a parametric curve:
$$( log {‖ {Ax}_{λ} - b ‖}_{2} , log {‖ {Lx}_{λ} ‖}_{2} ) ;$$
wherein as λ changes, the curve shows a trade-off under different regularization strengths:
for a small λ region: a data fitting residual is small, a solution norm is large, the curve is approximately horizontal, and the residual change is slow;
for a large λ region: the solution norm is small, the residual increases rapidly, the curve is approximately vertical, and the solution norm changes slowly;
for an inflection point region, a curvature is largest at an inflection point that balances data fitting with solution smoothness, corresponding to an optimal λ;
the inflection point corresponds to a point with the largest curvature, wherein calculation steps are as follows:
parameterizing curve: defining the L-curve as a function η(ρ), wherein
$$ρ = log ‖ {Ax}_{λ} - b ‖ ;$$
$$η = log ‖ {Lx}_{λ} ‖$$
calculating a curvature:
$$κ ( λ ) = \frac{ρ′η″ - ρ″η′}{{( {( ρ′ )}^{2} + {( η′ )}^{2} )}^{3 / 2}} ;$$
selecting a maximum curvature point: the corresponding λ is an optimal value;
wherein a L-curve criterion is used to achieve the adaptive regularization parameter, an optimal β is selected by a trade-off curve between a data fitting difference Φ_{d} and a model complexity Φₘ, wherein for the generated anisotropic weights, the different λ values are traversed, and the inversion calculation residual and solution norm are executed, finally, the L-curve inflection point is identified to ensure that the inversion model not only fits the data but also maintains the structural characteristics, wherein the initial β is estimated to be:
$${β}_{0} = \frac{{Φ}_{d}}{{( {( ρ′ )}^{2} + {( η′ )}^{2} )}^{3 / 2}} ;$$
where Φ_{d} is a difference of data fitting, and a denominator denotes an anisotropic feature of the model complexity;
$${β}_{k + 1} = \frac{{β}_{k}}{γ} ;$$
wherein γ is a cooling factor, βₖ denotes a regularization parameter of the k^{th} iteration, and β is a cooling strategy;
the inversion is defined by the root mean square (RMS) between the model response and the measured data:
$$RMS = \sqrt{\frac{{{\sum }_{i = 1}^{N} [ \frac{( {d}_{i}^{obs} - {d}_{i}^{fwd} )}{{σ}_{i}} ]}^{2}}{N}} ;$$
where
$${d}_{i}^{obs}$$
denotes measured i^{th} data,
$${d}_{i}^{fwd}$$
denotes i^{th} data of a forward calculation, σᵢ is a measurement standard deviation of the i^{th} data, and N is a total number of data.

10. The 3D inversion method of the DC method using seismic data constraints according to claim 9, wherein in step S3, the regularization term generation with seismic data constraint weight comprises the following steps:
a projection of a main feature vector in each direction is denoted as:
$$\{ \begin{matrix}{d}_{x} = \vert {V}_{1} \cdot {e}_{x} \vert \\ {d}_{y} = \vert {V}_{1} \cdot {e}_{y} \vert \\ {d}_{z} = \vert {V}_{1} \cdot {e}_{z} \vert\end{matrix} ;$$
an anisotropic strength is:
$$A = 1 - {e}^{- k \frac{{λ}_{1}}{{λ}_{3} + ϵ}} ;$$
a final x-direction weight is:
$${w}_{x} = \{ \begin{matrix}{d}_{x} = 2 ( 1 + {d}_{x} ) & S > {τ}_{coh} \\ {d}_{x} = 0.5 ( 1 - {d}_{x} ) & S < {τ}_{edge} \\ 1 & else\end{matrix} ;$$
where eₓ, e_{y}, and e_{z} denote standard basis vectors, which are unit vectors in the x, y, and z axes;
for a direction vector v=(a, b, c), a one-direction regularization term decomposition is denoted as:
$${φ}_{v} ( m ) = {α}_{s} {‖ m ‖}^{2} + \frac{a {α}_{x}}{\sum \vert {v}_{i} \vert} {‖ {W}_{x} {\partial }_{x} m ‖}^{2} + \frac{b {α}_{y}}{\sum \vert {v}_{i} \vert} {‖ {W}_{y} {\partial }_{y} m ‖}^{2} + \frac{c {α}_{x}}{\sum \vert {v}_{i} \vert} {‖ {W}_{z} {\partial }_{z} m ‖}^{2} ;$$
where Σ|vᵢ| is a sum of an absolute value of the direction vector, αₛ is a regularization parameter of a model norm, αₓ, α_{y}, and α_{z} denote regularization parameters of gradient terms in the x, y, z directions;
$$\sum \vert {v}_{i} \vert = \vert a \vert + \vert b \vert + \vert c \vert ;$$
anisotropic regularization is formed by summing three orthogonal direction regularization terms:
$${φ}_{m} ( m ) = {φ}_{x} ( m ) + {φ}_{y} ( m ) + {φ}_{z} ( m ) ;$$
where φₘ(m) is a regularization term, and m is a model vector.
